(19) United States
(12) Patent Application Publication
(10) Pub. No.: US 2020/0019060 A1
(43) Pub. Date: Jan. 16, 2020

(54) PHOTOSENSITIVE RESIN COMPOSITION, PHOTOSENSITIVE RESIN COMPOSITION FILM, INSULATING FILM, AND ELECTRONIC COMPONENT

(71) Applicant: TORAY INDUSTRIES, INC., Tokyo (JP)

(72) Inventors: Yuki KATSURADA, Shiga (JP); Daisuke KANAMORI, Shiga (JP)

(73) Assignee: TORAY INDUSTRIES, INC., Tokyo (JP)

(21) Appl. No.: 16/494,670

(22) PCT Filed: Mar. 12, 2018
(86) PCT No.: PCT/JP2018/009545

§ 371 Date: Sep. 16, 2019

(30) Foreign Application Priority Data
Mar. 21, 2017 (JP) 2017-053957

(51) Int. Cl. G03F 7/038

(52) U.S. Cl. CPC G03F 7/0387

(57) ABSTRACT

A photosensitive resin composition contains an alkali-soluble polyimide (a), an unsaturated bond-containing compound (b), a heat-crosslinkable compound (c), and a photopolymerization initiator (d) having a structure represented by the following general formula (1):

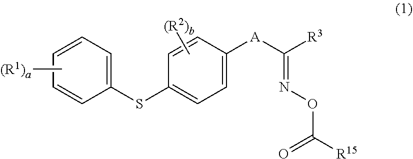

wherein, R¹ to R³ each independently represents a halogen atom, a hydroxy group, a carboxy group, a nitro group, a cyano group, —NR¹³R¹⁴, a monovalent hydrocarbon group having a carbon number of 1 to 20, an acyl group having a carbon number of 1 to 20, or an alkoxy group having a carbon number of 1 to 20; R¹³ and R¹⁴ each independently represents a hydrogen atom or an alkyl group having a carbon number of 1 to 10; R¹⁵ represents an alkyl group having a carbon number of 1 to 5; a represents an integer of 0 to 5 and b represents an integer of 0 to 4; and A represents CO or a direct bond.

### FIELD

The present invention relates to a photosensitive resin composition, a photosensitive resin composition film, an insulating film, and an electronic component.

### BACKGROUND

Polyimides have excellent electric properties, mechanical properties, and heat resistance and thus are useful for applications such as the surface protective film and an interlayer insulating film of a semiconductor element, a wire protective insulating film of a circuit board. In recent years, a photosensitive polyimide resin composition imparted with photosensitivity is used in these applications because the photosensitive polyimide resin composition can reduce the number of processes.

So far, as the photosensitive polyimide resin composition, a photosensitive resin composition containing a polyimide or polyimide precursor having an unsaturated carbon-carbon double bond and a compound generating a radical by actinic ray radiation has been developed (for example, refer to Patent Literature 1). In order to close the ring of the polyimide precursor, however, a heat treatment at high temperature above 300° C. is required and thus a copper circuit is easily oxidized. Consequently, problems of the electrical properties and reliability of an electronic component have arisen.

Therefore, as a photosensitive resin composition using polyimide having the already closed ring, a photosensitive resin composition containing a polyimide having at least one group selected from the group consisting of a carboxy group, a phenolic hydroxy group, a sulfonic acid group, and a thiol group at the end of the main chain, a polymerizable compound containing an unsaturated bond, an imidazole silane, and a photopolymerization initiator has been developed (for example, refer to Patent Literature 2). A photo-patterning of the polyimide resin composition is possible by using such techniques without requiring heat treatment at high temperature.

### CITATION LIST

### Patent Literature

Patent Literature 1: Japanese Patent Application Laid-open No. 2016-8992

Patent Literature 2: Japanese Patent Application Laid-open No. 2011-17897

### SUMMARY

### Technical Problem

In the case where the photosensitive resin composition described in Patent Literature 2 is processed in a thick film, however, sufficient photocuring to the deep part of the thick film of the photosensitive resin composition is difficult at an exposure process of photo-patterning due to large light absorption of the polyimide having the already closed ring. In this case, a pattern formed in the photosensitive resin composition easily forms an inverse tapered shape in a sectional shape (for example, a shape that becomes thin from the top to the bottom) or a constricted shape. This has raised a problem of difficulty in obtaining a rectangular pattern. In the case where the pattern having the inverse tapered shape or the constricted shape is used for a surface protective film and an interlayer insulating film of a semiconductor element, and a wire protective insulating film of a circuit board, embedding of a metal serving as an electric conductor is insufficient and thus conduction failure easily occurs. Therefore, formation of rectangular pattern is required.

The present invention has been made in view of the above circumstances. An object of the present invention is to provide a photosensitive resin composition that does not require heat treatment at high temperature and allows the pattern shape to be processed in a rectangular shape even in thick film processing and a photosensitive resin composition film, an insulating film, and an electronic component using the same.

### Solution to Problem

To solve the problem described above and to achieve the object, a photosensitive resin composition according to the present invention includes: an alkali-soluble polyimide (a), an unsaturated bond-containing compound (b), a thermally crosslinkable compound (c), and a photopolymerization initiator (d) having a structure represented by the following general formula (1):

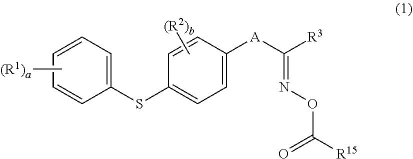

in the general formula (1), R¹ to R³ each independently represents a halogen atom, a hydroxy group, a carboxy group, a nitro group, a cyano group, —NR¹³R¹⁴, a monovalent hydrocarbon group having a carbon number of 1 to 20, an acyl group having a carbon number of 1 to 20, or an alkoxy group having a carbon number of 1 to 20; R¹³ and R¹⁴ each independently represents a hydrogen atom or an alkyl group having a carbon number of 1 to 10; at least some of the hydrogen atoms in the hydrocarbon group, the acyl group, and the alkoxy group are optionally substituted with halogen atoms, hydroxy groups, carboxy groups, nitro groups, cyano groups, or —NR¹³R¹⁴s; the hydrocarbon group and the hydrocarbon group in the alkoxy group are optionally divided by an ether bond, a thioether bond, an ester bond, a thioester bond, an amide bond, or a urethane bond; R¹⁵ represents an alkyl group having a carbon number of 1 to 5; a represents an integer of 0 to 5 and b represents an integer of 0 to 4; and A represents CO or a direct bond.

In the photosensitive resin composition according to the present invention, the photopolymerization initiator (d) has a structure represented by the following general formula (1-1):

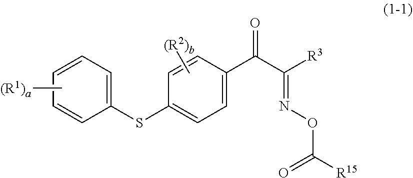

in the general formula (1-1), R¹ to R³ each independently represents a halogen atom, a hydroxy group, a carboxy group, a nitro group, a cyano group, —NR¹³R¹⁴, a monovalent hydrocarbon group having a carbon number of 1 to 20, an acyl group having a carbon number of 1 to 20, or an alkoxy group having a carbon number of 1 to 20; R¹³ and R¹⁴ each independently represents a hydrogen atom or an alkyl group having a carbon number of 1 to 10; at least some of the hydrogen atoms in the hydrocarbon group, the acyl group, and the alkoxy group are optionally substituted with halogen atoms, hydroxy groups, carboxy groups, nitro groups, cyano groups, or —NR¹³R¹⁴s; the hydrocarbon group and the hydrocarbon group in the alkoxy group are optionally divided by an ether bond, a thioether bond, an ester bond, a thioester bond, an amide bond, or a urethane bond; R¹⁵ represents an alkyl group having a carbon number of 1 to 5; a represents an integer of 0 to 5 and b represents an integer of 0 to 4.

In the photosensitive resin composition according to the present invention, the photopolymerization initiator (d) has a structure represented by the following general formula (1-2):

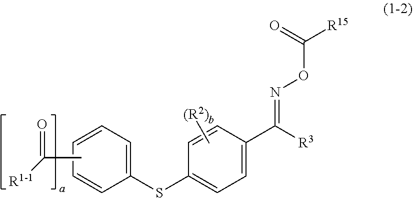

in the general formula (1-2), R¹⁻¹ represents a halogen atom, a hydroxy group, a carboxy group, a nitro group, a cyano group, —NR¹³R¹⁴, a monovalent hydrocarbon group having a carbon number of 1 to 20, or an alkoxy group having a carbon number of 1 to 20; R¹³ and R¹⁴ in R¹⁻¹ each independently represents a hydrogen atom or an alkyl group having a carbon number of 1 to 10; at least some of the hydrogen atoms in the hydrocarbon group and the alkoxy group in R¹⁻¹ are optionally substituted with halogen atoms, hydroxy groups, carboxy groups, nitro groups, cyano groups, or —NR¹³R¹⁴s; the hydrocarbon group and the hydrocarbon group in the alkoxy group in R¹⁻¹ are optionally divided by an ether bond, a thioether bond, an ester bond, a thioester bond, an amide bond, or a urethane bond; R² and R³ each independently represents a halogen atom, a hydroxy group, a carboxy group, a nitro group, a cyano group, —NR¹³R¹⁴, a monovalent hydrocarbon group having a carbon number of 1 to 20, an acyl group having a carbon number of 1 to 20, or an alkoxy group having a carbon number of 1 to 20; R¹³ and R¹⁴ in R² and R³ each independently represents a hydrogen atom or an alkyl group having a carbon number of 1 to 10; at least some of the hydrogen atoms in the hydrocarbon group, the acyl group, and the alkoxy group in R² and R³ are optionally substituted with halogen atoms, hydroxy groups, carboxy groups, nitro groups, cyano groups, or —NR¹³R¹⁴s; the hydrocarbon group and the hydrocarbon group in the alkoxy group in R² and R³ are optionally divided by an ether bond, a thioether bond, an ester bond, a thioester bond, an amide bond, or a urethane bond; R¹⁵ represents an alkyl group having a carbon number of 1 to 5; a represents an integer of 0 to 5 and b represents an integer of 0 to 4.

In the photosensitive resin composition according to the present invention, when an absorbance before exposure at a wavelength of 405 nm is determined to be Abs(0) and an absorbance after exposure at a wavelength of 405 nm is determined to be Abs(1), the photosensitive resin composition satisfies Abs(1)/Abs(0)<1.25.

In the photosensitive resin composition according to the present invention, the alkali-soluble polyimide (a) has at least one of a carboxy group, a phenolic hydroxy group, a sulfonic acid group, and a thiol group at an end of a main chain.

In the photosensitive resin composition according to the present invention, the alkali-soluble polyimide (a) has at least one of a carboxy group, a phenolic hydroxy group, a sulfonic acid group, and a thiol group in a side chain.

In the photosensitive resin composition according to the present invention, the alkali-soluble polyimide (a) has the phenolic hydroxy group in the side chain.

In the photosensitive resin composition according to the present invention, the alkali-soluble polyimide (a) is a polyimide having a residue of a siloxanediamine.

In the photosensitive resin composition according to the present invention, the alkali-soluble polyimide (a) is a polyimide containing the residue of the siloxane diamine in an amount of 1% by mole or more and 10% by mole or less in total diamine residues.

In the photosensitive resin composition according to the present invention, an imidation ratio of the alkali-soluble polyimide (a) is 70% or more.

A photosensitive resin composition film according to the present invention includes the photosensitive resin composition according to any one of the above-described inventions.

An insulating film according to the present invention includes a cured product of the photosensitive resin composition according to any one of the above-described inventions.

An electronic component according to the present invention includes the insulating film according to the above-described invention.

The electronic component according to the present invention includes a hollow structure body including a roof part made of the insulating film.

### Advantageous Effects of Invention

According to the present invention, effects that do not require heat treatment at high temperature and that allow the pattern shape to be processed in a rectangular shape even in thick film processing can be exhibited.

### DESCRIPTION OF EMBODIMENTS

Hereinafter, suitable embodiments of the photosensitive resin composition, the photosensitive resin composition film, the insulating film, and the electronic component according to the present invention will be described in detail. The present invention, however, is not limited to the following embodiments and can be implemented with various modifications depending on the purpose and application.

<Photosensitive Resin Composition>

The photosensitive resin composition according to the present invention contains an alkali-soluble polyimide (a), an unsaturated bond-containing compound (b), a thermally crosslinkable compound (c), and a photopolymerization initiator (d). In the present embodiment, the alkali-soluble polyimide (a) is an alkali-soluble polyimide having an already closed ring. The unsaturated bond-containing compound (b) is a compound containing an unsaturated bond. The thermally crosslinkable compound (c) is a compound having a thermally crosslinkable property. The photopolymerization initiator (d) is a photopolymerization initiator having the structure represented by the following general formula (1).

The photosensitive resin composition according to the present invention contains the alkali-soluble polyimide having the already closed ring and thus, different from a resin composition containing a polyimide precursor, conversion of the polyimide precursor into a polyimide by heat treatment at high temperature is not required. Therefore, the photosensitive resin composition according to the present invention does not require the heat treatment at high temperature and allows stress caused by curing shrinkage due to imide ring closure reaction to be reduced.

In addition, the photosensitive resin composition according to the present invention contains the alkali-soluble polyimide (a), the unsaturated bond-containing compound (b), and the photopolymerization initiator (d) and thus the resin composition can be easily dissolved in an alkaline development liquid before exposure and can form a negative-type pattern insoluble in the alkaline development liquid after exposure. The photopolymerization initiator (d) has the structure represented by the following general formula (1) and thus cleaves an N—O bond by exposure. This generates iminyl radicals and acetyloxy radicals. Subsequently, these iminyl radicals and acetyloxy radicals are further cleaved by thermal decomposition. This cleavage cleaves a conjugated system of the photopolymerization initiator (d) and thus light absorption of the photopolymerization initiator (d) becomes smaller due to color fading. Therefore, sufficient photo-curing can be achieved to the deep part of the photosensitive resin composition by selecting the photopolymerization initiator (d) having the structure represented by the following general formula (1) as the photopolymerization initiator in the photosensitive resin composition according to the present invention. Consequently, even when the thick film of the photosensitive resin composition containing the alkali-soluble polyimide (a) having the already closed ring having large light absorption is processed, the pattern shape in the thick film of this photosensitive resin composition can be processed in a rectangular shape. In addition, this thick film of the photosensitive resin composition generates highly reactive alkyl radicals having a carbon number of 1 to 5 by cleaving the acetyloxy radicals and thus the pattern in the thick film having excellent surface curability and a high residual film ratio can be obtained.

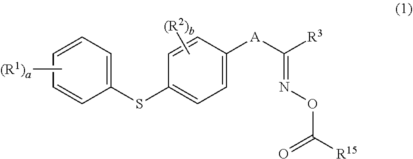

In the general formula (1), R¹ to R³ each independently represents a halogen atom, a hydroxy group, a carboxy group, a nitro group, a cyano group, —NR¹³R¹⁴, a monovalent hydrocarbon group having a carbon number of 1 to 20, an acyl group having a carbon number of 1 to 20, or an alkoxy group having a carbon number of 1 to 20. R¹³ and R¹⁴ each independently represents a hydrogen atom or an alkyl group having a carbon number of 1 to 10. Here, at least some of the hydrogen atoms in the hydrogen atoms of the above-described hydrocarbon group, acyl group, and alkoxy group described above may be substituted with halogen atoms, hydroxy groups, carboxy groups, nitro groups, cyano groups, or —NR¹³R¹⁴s. The hydrocarbon group or the hydrocarbon group in the alkoxy group described above may be divided by an ether bond, a thioether bond, an ester bond, a thioester bond, an amide bond, or a urethane bond. R¹⁵ represents an alkyl group having a carbon number of 1 to 5. a represents an integer of 0 to 5 and b is an integer of 0 to 4. A represents CO or a direct bond.

In the photosensitive resin composition according to the present invention, the alkali-soluble polyimide (a) refers to a polyimide having a solubility into an 2.38% by mass tetramethylammonium aqueous solution of 0.1 g/100 g or more at a temperature of 23° C.

In addition, in the present embodiment, for example, a “monovalent hydrocarbon group having a carbon number of 1 to 20” means a monovalent hydrocarbon group that has a carbon number of 1 to 20. The other groups and radicals in which the carbon number is defined have the same meaning as this meaning.

(Alkali-Soluble Polyimide)

The alkali-soluble polyimide (a) preferably has at least one of a carboxy group, a phenolic hydroxy group, a sulfonic acid group, and a thiol group at the end of the main chain. This is because this constitution allows the alkali solubility of the alkali-soluble polyimide (a) to be improved. In view of practicality to an alkaline development liquid generally used in the semiconductor industry, the alkali-soluble polyimide (a) preferably has the phenolic hydroxy group or the thiol group at the end of the main chain. Here, the carboxy group, the phenolic hydroxy group, the sulfonic acid group, or the thiol group can be introduced to the end of the main chain by using terminal blocking agents having these groups. Blocking of the end of the main chain allows the number of the repeating units in the alkali-soluble polyimide (a) to be appropriately small. Therefore, the photosensitive resin composition containing the alkali-soluble polyimide (a) allows processability of the fine pattern of the composition to be improved.

As the alkali-soluble polyimide (a) having at least one of the carboxy group, the phenolic hydroxy group, the sulfonic acid group, and the thiol group at the end of the main chain, for example, a polyimide having the structure of the following general formula (2) or the following general formula (3) is preferable.

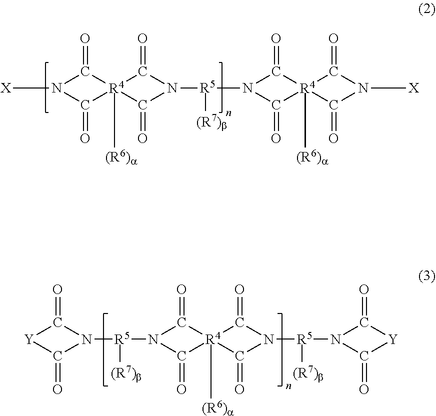

In the general formulas (2) and (3), X represents a monovalent organic group having at least one of a carboxy group, a phenolic hydroxy group, a sulfonic acid group, and a thiol group. Y represents a divalent organic group having at least one of a carboxy group, a phenolic hydroxy group, a sulfonic acid group, and a thiol group. X and Y preferably have the phenolic hydroxy group or the thiol group, and particularly preferably having the phenolic hydroxy group.

R⁴ represents a 4- to 14-valent organic group and R⁵ represents a 2- to 12-valent organic group. R⁶ and R⁷ each independently represents a carboxy group, a phenolic hydroxy group, a sulfonic acid group, or a thiol group. R⁶ and R⁷ are preferably a phenolic hydroxy group or a thiol group and particularly preferably the phenolic hydroxy group.

In addition, α and β each independently represents an integer in the range of 0 to 10. In such α and β, α+β is preferably 1 or more. n represents the number of repeat of the structure units in the polymer. The range of this n is 3 to 200. The polymer having n of 3 or more allows the thick film processability of the photosensitive resin composition to be improved. From the viewpoint of improving the thick film processability, n is preferably 5 or more. On the other hand, the polymer having n of 200 or less allows the solubility of the alkali-soluble polyimide (a) into an alkaline development liquid to be improved. From the viewpoint of the solubility improvement, n is preferably 100 or less. In each polymer chain, n is an integer. However, n determined by analysis of the alkali-soluble polyimide (a) may fail to be an integer.

In the general formulas (2) and (3), R⁴ is a 4- to 14-valent organic group having a structure derived from a tetracarboxylic acid dianhydride. Such R⁴ is preferably an organic group containing an aromatic group or a cycloaliphatic group and having a carbon number of 5 to 40.

Examples of the tetracarboxylic acid dianhydride include an aromatic tetracarboxylic acid dianhydride and an aliphatic tetracarboxylic acid dianhydride. Examples of the aromatic tetracarboxylic acid dianhydride include pyromellitic acid dianhydride, 3,3′,4,4′-biphenyltetracarboxylic acid dianhydride, 2,3,3′,4′-biphenyltetracarboxylic acid dianhydride, 2,2′,3,3′-biphenyltetracarboxylic acid dianhydride, 3,3′,4,4′-benzophenonetetracarboxylic acid dianhydride, 2,2′,3,3′-benzophenonetetracarboxylic acid dianhydride, 2,2-bis(3,4-dicarboxyphenyl)propane dianhydride, 2,2-bis(2,3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, bis(3,4-dicarboxyphenyl)sulfone dianhydride, bis-(3-phthalyl anhydride) ether, 1,2,5,6-naphthalenetetracarboxylic acid dianhydride, 9,9-bis(3,4-carboxyphenyl)fluorene acid dianhydride, 9,9-bis{4-(3,4-dicarboxyphenoxy)phenyl}fluorene acid dianhydride, 2,3,6,7-naphthalenetetracarboxylic acid dianhydride, 2,3,5,6-pyridinetetracarboxylic acid dianhydride, 3,4,9,10-perylenetetracarboxylic acid dianhydride, and 2,2-bis(3,4-dicarboxyphenyl)hexafluoropropane dianhydride. Examples of the aliphatic tetracarboxylic acid dianhydrides include butanetetracarboxylic acid dianhydride and 1,2,3,4-cyclopentanetetracarboxylic acid dianhydride.

In addition, as the tetracarboxylic acid dianhydride, an acid dianhydride having the following structure can be included. In the present embodiment, two or more acid dianhydrides in the aromatic tetracarboxylic acid dianhydride, the aliphatic tetracarboxylic acid dianhydride and the acid dianhydride having the following structure described above may be used.

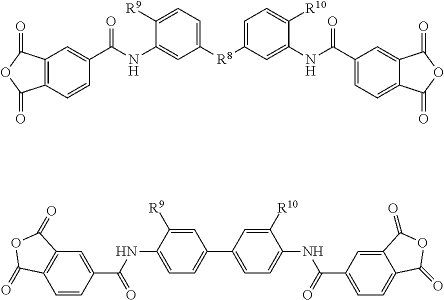

In the general formula representing the acid dianhydride having the structure, R⁸ represents an oxygen atom, C(CF₃)₂, C(CH₃)₂, or SO₂. R⁹ and R¹⁰ each independently represents a hydroxy group or a thiol group.

In addition, in the general formulas (2) and (3), R⁵ is a 2- to 12-valent organic group having a structure derived from a diamine. Such R⁵ is preferably an organic group containing an aromatic group or a cycloaliphatic group and having a carbon number of 5 to 40.

Examples of the diamine include hydroxy group-containing diamines, thiol group-containing diamines, aromatic diamines, compounds in which at least some of the hydrogen atoms of the aromatic rings are substituted with alkyl groups or halogen atoms, and an aliphatic diamine.

Examples of the hydroxy group-containing diamines include bis-(3-amino-4-hydroxyphenyl)hexafluoropropane, bis(3-amino-4-hydroxyphenyl)sulfone, bis(3-amino-4-hydroxyphenyl)propane, bis(3-amino-4-hydroxyphenyl)methylene, bis(3-amino-4-hydroxyphenyl) ether, bis(3-amino-4-hydroxy)biphenyl, and bis(3-amino-4-hydroxyphenyl)fluorene. Examples of the thiol group-containing diamine include dimercaptophenylenediamine.

Examples of the aromatic diamines include 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylmethane, 3,3′-diaminodiphenylsulfone, 3,4′-diaminodiphenylsulfone, 4,4′-diaminodiphenylsulfone, 3,4′-diaminodiphenylsulfide, 4,4′-diaminodiphenylsulfide, 1,4-bis(4-aminophenoxy)benzene, 1,3-bis(4-aminophenoxy)benzene, 1,3-bis(3-aminophenoxy)benzene, benzidine, m-phenylenediamine, p-phenylene diamine, 1,5-naphthalenediamine, 2,6-naphthalenediamine, bis(4-aminophenoxyphenyl)sulfone, bis(3-aminophenoxyphenyl)sulfone, bis(4-aminophenoxy)biphenyl, bis{4-(4-aminophenoxy)phenyl} ether, 1,4-bis(4-aminophenoxy)benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, 2,2′-di(trifluoromethyl)-4,4′-diaminobiphenyl, and 9,9-bis(4-aminophenyl)fluorene. Examples of the aliphatic diamines include cyclohexyldiamine and methylenebiscyclohexylamine.

Examples of the diamine also include a diamine having the following structure. In the present embodiment, two or more diamines in the hydroxy group-containing diamines, the thiol group-containing diamines, and the aromatic diamines described above, compound in which at least some of the hydrogen atoms of these aromatic rings are substituted with alkyl groups or halogen atoms, the aliphatic diamines, and the diamines having the following structure may be used.

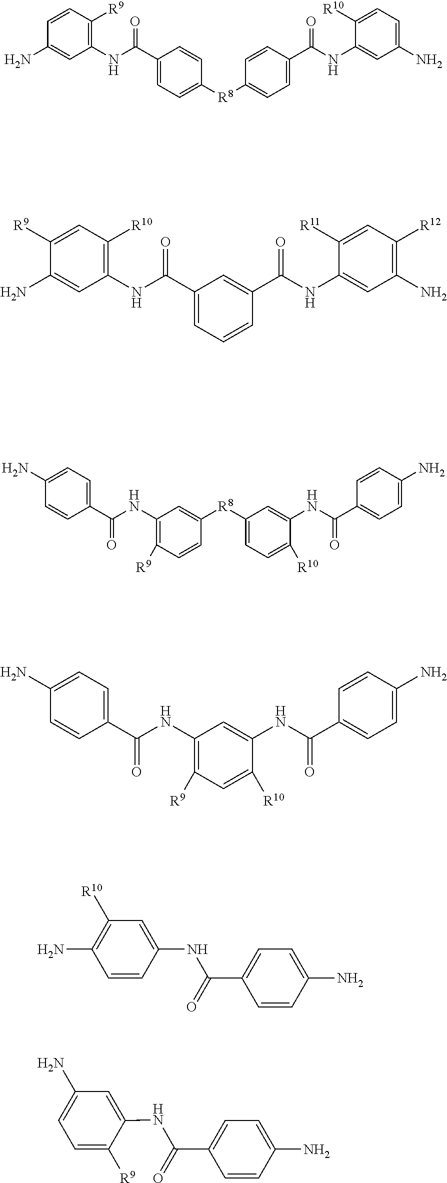

In the general formula representing the diamine having the structure, R⁸ represents an oxygen atom, C(CF₃)₂, C(CH₃)₂, or SO₂. R⁹ to R¹² each independently represents a hydroxy group or a thiol group.

Of the above-described diamines, bis-(3-amino-4-hydroxyphenyl)hexafluoropropane, bis(3-amino-4-hydroxyphenyl)sulfone, bis(3-amino-4-hydroxyphenyl)propane, bis(3-amino-4-hydroxyphenyl)methylene, bis(3-amino-4-hydroxyphenyl) ether, bis(3-amino-4-hydroxy)biphenyl, bis(3-amino-4-hydroxyphenyl)fluorene, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylmethane, 3,3′-diaminodiphenylsulfone, 3,4′-diaminodiphenylsulfone, 4,4′-diaminodiphenylsulfone, 3,4′-diaminodiphenylsulfide, 4,4′-diaminodiphenylsulfide, m-phenylenediamine, p-phenylenediamine, 1,4-bis(4-aminophenoxy)benzene, 9,9-bis(4-aminophenyl)fluorene, and the diamines having the following structures are preferable.

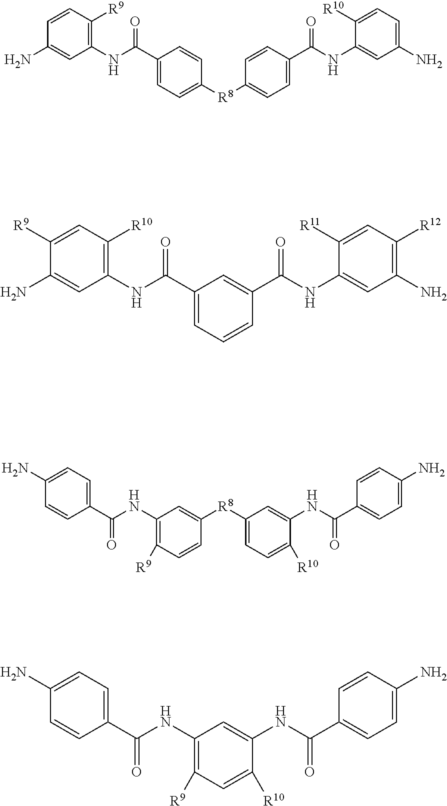

In addition, in the general formulas (2) and (3), R⁶ and R⁷ each independently represents a carboxy group, a phenolic hydroxy group, sulfonic acid group, or a thiol group as described above. The dissolution rate of the alkali-soluble polyimide (a) into an aqueous alkali solution is changed by adjusting the amount of alkali-soluble groups in these R⁶ and R⁷ and thus the photosensitive resin composition having a desired dissolution rate can be obtained.

In addition, in the alkali-soluble polyimide (a) having the structure represented by the general formulas (2) and (3), an aliphatic compound having a siloxane structure may be copolymerized to R⁵ within a range not deteriorating the heat resistance. The copolymerization of the aliphatic compound having a siloxane structure allows the transparence of the alkali-soluble polyimide (a) to be improved, adhesion between the alkali-soluble polyimide (a) and a substrate to be improved, and laminating when the alkali-soluble polyimide (a) is used in the photosensitive resin composition film to be facilitated. Examples of the aliphatic compound having a siloxane structure include, in the case of a diamine, 1,3-bis(3-aminopropyl)tetramethyldisiloxane and 1,3-bis(p-aminophenyl)octamethylpentasiloxane. These compounds are preferably copolymerized in an amount of 1% by mole to 10% by mole in the total diamines in the alkali-soluble polyimide (a).

In addition, in the general formula (2), X is derived from a primary monoamine serving as a terminal blocking agent. Preferable examples of the primary monoamine serving as the terminal blocking agent include 5-amino-8-hydroxyquinoline, 1-hydroxy-7-aminonaphthalene, 1-hydroxy-6-aminonaphthalene, l-hydroxy-5-aminonaphthalene, l-hydroxy-4-aminonaphthalene, 2-hydroxy-7-aminonaphthalene, 2-hydroxy-6-aminonaphthalene, 2-hydroxy-5-aminonaphthalene, l-carboxy-7-aminonaphthalene, l-carboxy-6-aminonaphthalene, l-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 2-aminobenzenesulfonic acid, 3-aminobenzenesulfonic acid, 4-aminobenzenesulfonic acid, 3-amino-4,6-dihydroxypyrimidine, 2-aminophenol, 3-aminophenol, 4-aminophenol, 2-aminothiophenol, 3-aminothiophenol, and 4-aminothiophenol. As such a terminal blocking material, two or more of these primary amines may be used.

In addition, in the general formula (3), Y is derived from a dicarboxylic acid anhydride serving as a terminal blocking agent. Preferable examples of this dicarboxylic acid anhydride serving as the terminal blocking agent include 4-carboxyphthalic acid anhydride, 3-hydroxyphthalic acid anhydride, and cis-aconitic acid anhydride. As such a terminal blocking material, two or more dicarboxylic acid anhydrides in these dicarboxylic acid anhydrides may be used.

The alkali-soluble polyimide (a) in the present invention may include an alkali-soluble polyimide having a structure other than the structure represented by the general formula (2) or the general formula (3). In this case, the alkali-soluble polyimide having the structure represented by the general formula (2) or the general formula (3) is preferably contained in an amount of 30% by mass or more and more preferably contained in an amount of 60% by mass or more relative to the total mass of the alkali-soluble polyimide (a). The photosensitive resin composition containing the alkali-soluble polyimide having the structure represented by the general formula (2) or (3) in an amount of 30% by mass or more allows the shrinkage during thermal curing of the alkali-soluble polyimide (a) to be reduced and thus is more suitable for the thick film processing of the photosensitive resin composition. The type of the alkali-soluble polyimide having a structure other than the structure represented by the general formula (2) or the general formula (3) and the content in the alkali-soluble polyimide (a) is preferably selected in the range of not impairing the heat resistance of the alkali-soluble polyimide (a) obtained by the final heat treatment and the solubility into the alkaline development liquid.

The alkali-soluble polyimide (a) can be synthesized by employing any method in which a part of the diamine is replaced to the monoamine serving as the terminal blocking agent or the tetracarboxylic acid dianhydride is replaced with a dicarboxylic acid anhydride serving as the terminal blocking agent. The alkali-soluble polyimide (a) can be synthesized by, for example, the first method of reacting the tetracarboxylic acid dianhydride with the diamine compound, and the monoamine at a low temperature, the second method of reacting the tetracarboxylic acid dianhydride and dicarboxylic acid anhydride with the diamine compound at a low temperature, and the third method of employing a method for obtaining a diester from the tetracarboxylic acid dianhydride and an alcohol and thereafter using a method of reacting this diester with the diamine and the monoamine in the presence of a condensing agent to give a polyimide precursor or the like and thereafter fully imidizing the obtained polyimide precursor by using any imidation reactions.

From the viewpoints of improving electric properties, mechanical properties, heat resistance, moisture resistance, and the residual film ratio, in the present invention, the imidation ratio of the alkali-soluble polyimide (a) is preferably 70% or more. The imidation ratio is more preferably 80% or more and further preferably 90% or more. Examples of methods for controlling the imidation ratio of the alkali-soluble polyimide (a) within the above range include a method for carrying out the imidation reaction under a dry nitrogen gas stream at a reaction temperature of 160° C. or more for a reaction time of 2 hours or more.

Here, the imidation ratio of the alkali-soluble polyimide (a) in the present invention can be determined by the following method. First, the infrared absorption spectrum of the alkali-soluble polyimide (a) is measured to determine the peak intensity P1 of a peak in the vicinity of 1377 cm⁻¹ being an absorption peak attributed to an imide structure. Subsequently, the alkali-soluble polyimide (a) is subjected to heat treatment at 350° C. for 1 hour and thereafter the infrared absorption spectrum is measured to determine the peak intensity P2 of the peak in the vicinity of 1377 cm⁻¹. Use of the obtained peak intensities P1, P2 allows the imidation ratio of the alkali-soluble polyimide (a) to be determined in accordance with the following formula.

Imidation ratio [%]=(Peak intensity P1/Peak intensity P2)×100

In addition, the alkali-soluble polyimide (a) in the present invention may have at least one of a carboxy group, a phenolic hydroxy group, a sulfonic acid group, and a thiol group in the side chain. Of these groups, the alkali-soluble polyimide (a) preferably has the phenolic hydroxy group in the side chain.

In addition, the alkali-soluble polyimide (a) in the present invention may be a polyimide having the residue of a siloxanediamine. In this case, the residue of the siloxanediamine is preferably contained in an amount of 1% by mole or more and 10 mol % by mole or less in the total diamine residues in the alkali-soluble polyimide (a).

On the other hand, the terminal blocking agent introduced into the alkali-soluble polyimide (a) can be detected by the following method. For example, the alkali-soluble polyimide (a) to which the terminal blocking agent is introduced is dissolved in an acidic solution to decompose the alkali-soluble polyimide (a) into the amine component and the carboxylic acid anhydride component serving as the constitutional unit of the polyimide. Subsequently, these amine component and carboxylic acid anhydride component are analyzed by gas chromatography (GC) or NMR to allow the terminal blocking agent of the alkali-soluble polyimide (a) to be detected. In addition, the alkali-soluble polyimide (a) to which the terminal blocking agent is introduced is directly analyzed by using pyrolysis gas chromatography (PGC), infrared spectrum, and ¹³CNMR spectrum to allow the terminal blocking agent of the alkali-soluble polyimide (a) also to be detected.

(Unsaturated Bond-Containing Compound)

The photosensitive resin composition according to the present invention contains the unsaturated bond-containing compound (b). Examples of the unsaturated bond-containing group in the unsaturated bond-containing compound (b) include unsaturated double bond-containing groups such as a vinyl group, an allyl group, an acryloyl group, and a methacryloyl group and unsaturated triple bond-containing groups such as a propargyl group. The unsaturated bond-containing compound (b) may contain two or more of these unsaturated bond-containing groups. Of these groups, the conjugated vinyl group, acryloyl group, and methacryloyl group are preferable in the viewpoint of polymerizability. In addition, from the viewpoint of preventing cracks that are classified as being caused by excessive crosslinking points due to the polymerization reaction, the number of unsaturated bonds in unsaturated bond-containing compound (b) is preferably 1 to 6.

Examples of the unsaturated bond-containing compound (b) include diethylene glycol diacrylate, triethylene glycol diacrylate, tetraethylene glycol diacrylate, diethylene glycol dimethacrylate, triethylene glycol dimethacrylate, tetraethylene glycol dimethacrylate, trimethylolpropane diacrylate, trimethylolpropane triacrylate, trimethylolpropane dimethacrylate, trimethylolpropane trimethacrylate, styrene, α-methylstyrene, 1,2-dihydronaphthalene, 1,3-diisopropenylbenzene, 3-methylstyrene, 4-methylstyrene, 2-vinylnaphthalene, butyl acrylate, butyl methacrylate, isobutyl acrylate, hexyl acrylate, isooctyl acrylate, isobornyl acrylate, isobornyl methacrylate, cyclohexyl methacrylate, 1,3-butanediol diacrylate, 1,3-butanediol dimethacrylate, neopentyl glycol diacrylate, 1,4-butanediol diacrylate, 1,4-butanediol dimethacrylate, 1,6-hexanediol diacrylate, 1,6-hexanediol dimethacrylate, 1,9-nonanediol dimethacrylate, 1,10-decanediol dimethacrylate, dimethylol-tricyclodecane diacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, 2-hydroxyethyl acrylate, 2-hydroxyethyl methacrylate, 1,3-diacryloyloxy-2-hydroxypropane, 1,3-dimethacryloyloxy-2-hydroxypropane, methylene-bis-acrylamide, N,N-dimethylacrylamide, N-methylolacrylamide, 2,2,6,6-tetramethylpiperidinyl methacrylate, 2,2,6,6-tetramethylpiperidinyl acrylate, N-methyl-2,2,6,6-tetramethylpiperidinyl methacrylate, N-methyl-2,2,6,6-tetramethylpiperidinyl acrylate, ethylene oxide-modified bisphenol A diacrylate, ethylene oxide-modified bisphenol A dimethacrylate, propylene oxide-modified bisphenol A diacrylate, propylene oxide-modified bisphenol A methacrylate, propoxylated ethoxylated bisphenol A diacrylate, propoxylated ethoxylated bisphenol A dimethacrylate, N-vinylpyrrolidone, and N-vinylcaprolactam. The unsaturated bond-containing compound (b) may include two or more of these compounds.

Of these compounds, 1,9-nonanediol dimethacrylate, 1,10-decanediol dimethacrylate, dimethylol-tricyclodecane diacrylate, isobornyl acrylate, isobornyl methacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, methylene-bis-acrylamide, N,N-dimethylacrylamide, N-methylolacrylamide, 2,2,6,6-tetramethylpiperidinyl methacrylate, 2,2,6,6-tetramethylpiperidinyl acrylate, N-methyl-2,2,6,6-tetramethylpiperidinyl methacrylate, N-methyl-2,2,6,6-tetramethylpiperidinyl acrylate, ethylene oxide-modified bisphenol A diacrylate, ethylene oxide-modified bisphenol A dimethacrylate, propylene oxide-modified bisphenol A diacrylate, propylene oxide-modified bisphenol A methacrylate, propoxylated ethoxylated bisphenol A diacrylate, propoxylated ethoxylated bisphenol A dimethacrylate, N-vinylpyrrolidone, and N-vinylcaprolactam are preferable as the unsaturated bond-containing compound (b). Of these compounds, dipentaerythritol hexaacrylate, dipentaerythritol hexamethacrylate, ethylene oxide-modified bisphenol A diacrylate, ethylene oxide-modified bisphenol A dimethacrylate, propylene oxide-modified bisphenol A diacrylate, and propylene oxide-modified bisphenol A methacrylate are more preferable.

From the viewpoint of improving the residual film ratio after development, the content of the unsaturated bond-containing compound (b) in the photosensitive resin composition according to the present invention is preferably 40 parts by mass or more and more preferably 50 parts by mass or more relative to 100 parts by mass of the alkali-soluble polyimide (a). On the other hand, from the viewpoint of improving the heat resistance of a cured film, the content of the unsaturated bond-containing compound (b) is preferably 150 parts by mass or less and more preferably 100 parts by mass or less relative to 100 parts by mass of the alkali-soluble polyimide (a).

(Thermally Crosslinkable Compound)

The photosensitive resin composition according to the present invention contains the thermally crosslinkable compound (c). As the thermally crosslinkable compound (c), for example, a compound containing at least one of an alkoxymethyl group, a methylol group, and an epoxy group is preferable, and a compound containing at least two of alkoxymethyl groups, methylol groups, or epoxy groups is more preferable. The thermally crosslinkable compound (c) having at least two of these groups forms a crosslinked structure body by reacting the thermally crosslinkable compound (c) with the alkali-soluble polyimide (a) or reacting the thermally crosslinkable compound (c) with each other. Therefore, the cured film obtained after heat treatment of the thermally crosslinkable compound (c) can improve the mechanical properties and chemical resistance.

Examples of the compound containing the alkoxymethyl groups or the methylol groups in the thermally crosslinkable compound (c) include 46DMOC and 46DMOEP (these are trade names, manufactured by ASAHI YUKIZAI CORPORATION), DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DMLBisOC-P, DMOM-PC, DMOM-PTBP, DMOM-MBPC, TriML-P, TriML-35XL, TML-HQ, TML-BP, TML-pp-BPF, TML-BPE, TML-BPA, ML-BPAF, TML-BPAP, TMOM-BP, TMOM-BPE, TMOM-BPA, TMOM-BPAF, TMOM-BPAP, HML-TPPHBA, HML-TPHAP, HMOM-TPPHBA, and HMOM-TPHAP (these are trade names, manufactured by Honshu Chemical Industry Co., Ltd.), and “NIKALAC” (registered trademark) MX-290, “NIKALAC” MX-280, “NIKALAC” MX-270, “NIKALAC” MX-279, “NIKALAC” MW-100LM, and “NIKALAC” MX-750LM (these are trade names, manufactured by Sanwa Chemical Co., Ltd.). The thermally crosslinkable compound (c) may include two or more of these compounds.

Examples of the compound containing the epoxy groups in the thermally crosslinkable compound (c) include a bisphenol A type epoxy resin, a bisphenol F type epoxy resin, propylene glycol diglycidyl ether, polypropylene glycol diglycidyl ether, polymethyl(glycidyloxypropyl), and an epoxy group-containing silicone. Specific Examples include “EPICLON” (registered trademark) 850-S, “EPICLON” HP-4032, “EPICLON” HP-7200, “EPICLON” HP-820, “EPICLON” HP-4700, “EPICLON” EXA-4710, “EPICLON” HP-4770, “EPICLON” EXA-859CRP, “EPICLON” EXA-1514, “EPICLON” EXA-4880, “EPICLON” EXA-4850-150, “EPICLON” EXA-4850-1000, “EPICLON” EXA-4816, and “EPICLON” EXA-4822 (these are trade names, manufactured by DIC CORPORATION), “RIKARESIN” (registered trademark) BEO-60E, “RIKARESIN” BPO-20E, “RIKARESIN” HBE-100, and “RIKARESIN” DME-100 (these are trade names, manufactured by New Japan Chemical Co., Ltd.), EP-4003S and EP-4000S (these are trade names, manufactured by ADEKA CORPORATION), PG-100, CG-500, and EG-200 (these are trade names, manufactured by Osaka Gas Chemicals Co., Ltd.), NC-3000 and NC-6000 (these are trade names, manufactured by Nippon Kayaku Co., Ltd.), “EPOX” (registered trademark)-MK R508, “EPOX”-MK R540, “EPOX”-MK R710, “EPOX”-MK R1710, VG3101L, and VG3101M80 (these are trade names, manufactured by PRINTEC CORPORATION), and “Celloxide” (registered trademark) 2021P, “Celloxide” 2081, “Celloxide” 2083, and “Celloxide” 2085 (therse are trade names, manufactured by Daicel Corporation). The thermally crosslinkable compound (c) may include two or more of these compounds.

From the viewpoint of improving the heat resistance of the cured film, the content of the thermally crosslinkable compound (c) in the photosensitive resin composition according to the present invention is preferably 1 part by mass or more and more preferably 5 parts by mass or more relative to 100 parts by mass of the alkali-soluble polyimide (a). On the other hand, from the viewpoint of improving the residual film ratio after development, the content of the thermally crosslinkable compound (c) is preferably 70 parts by mass or less and more preferably 50 parts by mass or less relative to 100 parts by mass of the alkali-soluble polyimide (a).

(Photopolymerization Initiator)

The photosensitive resin composition according to the present invention contains the photopolymerization initiator (d) having a structure represented by the following general formula (1).

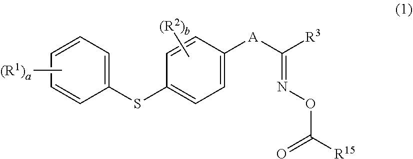

In the general formula (1), R¹ to R³ each independently represents a halogen atom, a hydroxy group, a carboxy group, a nitro group, a cyano group, —NR¹³R¹⁴, a monovalent hydrocarbon group having a carbon number of 1 to 20, an acyl group having a carbon number of 1 to 20, or an alkoxy group having a carbon number of 1 to 20. R¹³ and R¹⁴ each independently represents a hydrogen atom or an alkyl group having a carbon number of 1 to 10. Here, at least some of the hydrogen atoms in the above-described hydrocarbon group, acyl group, and alkoxy group may be substituted with halogen atoms, hydroxy groups, carboxy groups, nitro groups, cyano groups, or —NR¹³R¹⁴s. The above-described hydrocarbon group or the hydrocarbon group in the acyl group and the alkoxy group may be divided by an ether bond, a thioether bond, an ester bond, a thioester bond, an amide bond, or a urethane bond. R¹⁵ represents an alkyl group having a carbon number of 1 to 5. Of these groups, R³ is preferably a monovalent hydrocarbon group having a carbon number of 1 to 20 and more preferably a monovalent hydrocarbon group having a carbon number of 1 to 10. R¹ is preferably an acyl group having a carbon number of 1 to 20 or an alkoxy group having a carbon number of 1 to 20 and more preferably an acyl group having a carbon number or 1 to 10 or an alkoxy group having a carbon number of 1 to 10. In addition, the acyl group preferably has at least one of the aromatic ring and the ether bond. In the alkoxy group, some of the hydrogen atoms are preferably substituted with hydroxy groups.

In the general formula (1), a represents an integer of 0 to 5 and b represents an integer of 0 to 4. a is preferably “1” and b is preferably “0”.

In addition, in the present embodiment, the photopolymerization initiator (d) having the structure represented by the general formula (1) preferably has a structure represented by the following general formula (1-1) or the following general formula (1-2).

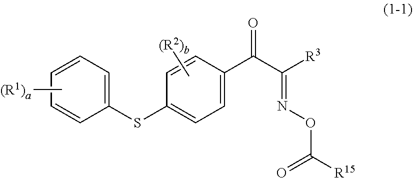

In the general formula (1-1), R¹ to R³, R¹⁵, a, and b are the same as those in the general formula (1).

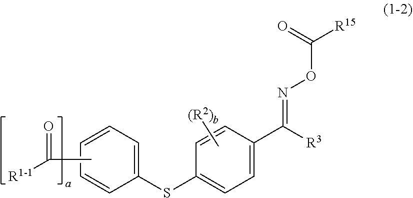

In the general formula (1-2), R², R³, R¹⁵, a, and b are the same as those in the general formula (1). R¹⁻¹ each independently represents a halogen atom, a hydroxy group, a carboxy group, a nitro group, a cyano group, —NR¹³R¹⁴, a monovalent hydrocarbon group having a carbon number of 1 to 20, or an alkoxy group having a carbon number of 1 to 20. R¹³ and R¹⁴ in R¹⁻¹ each independently represents a hydrogen atom or an alkyl group having a carbon number of 1 to 10. Here, at least some of the hydrogen atoms in the hydrocarbon group and the alkoxy group in R¹⁻¹ may be substituted with halogen atoms, hydroxy groups, carboxy groups, nitro groups, cyano groups, or —NR¹³R¹⁴s. The hydrocarbon group and the hydrocarbon group in the alkoxy group in R¹⁻¹ may be divided by an ether bond, a thioether bond, an ester bond, a thioester bond, an amide bond, or a urethane bond.

Examples of the photopolymerization initiator (d) having a structure represented by the general formula (1) include NCI-930 (trade name, manufactured by ADEKA CORPORATION) and some of the compounds described in WO 2015/036910 pamphlet.

From the viewpoint of effectively promoting the photocuring reaction of the unsaturated bond-containing compound (b) during exposure, the content of the photopolymerization initiator (d) in the photosensitive resin composition according to the present invention is preferably 1 part by mass or more, more preferably 3 parts by mass or more, further preferably 4 parts by mass or more, and most preferably 7 parts by mass or more relative to 100 parts by mass of the alkali-soluble polyimide (a). On the other hand, from the viewpoints of improving the transmittance of the photosensitive resin composition, more facilitating the formation of a rectangular shape pattern in a thick film, and reducing excessive polymerization reaction, the content of the photopolymerization initiator (d) is preferably 30 parts by mass or less, more preferably 20 parts by mass or less, further preferably 15 parts by mass or less, and most preferably 10 parts by mass or less relative to 100 parts by mass of the alkali-soluble polyimide (a).

(Other Ingredients)

The photosensitive resin composition of the present invention may further include a crosslinking agent other than the thermally crosslinkable compound (c), a photopolymerization initiator other than the photopolymerization initiator (d), additives such as a polymerization inhibitor, a coloring agent, a surfactant, a silane coupling agent, a titanium chelating agent, a crosslinking accelerator, a sensitizer, a dissolution adjuster, a stabilizer, a defoamer, and a filler and an organic solvent, if necessary.

Examples of the photopolymerization initiator other than the photopolymerization initiator (d) include oximes, benzophenones, benzylidenes, coumarins, anthraquinones, benzoins, thioxanthones, mercapto compounds, glycine compounds, oximes, benzyl dimethyl ketals, α-hydroxyalkylphenones, α-aminoalkylphenones, acylphosphine oxides, and 2,2′-bis(o-chlorophenyl)-4,4′,5,5′-tetraphenylbiimidazole. The photosensitive resin composition of the present invention may include two or more of these compounds as the photopolymerization initiator other than the photopolymerization initiator (d).

Of these compounds, the oximes and the acylphosphine oxides are preferable. Examples of the oximes include 1-phenyl-1,2-butanedione-2-(o-methoxycarbonyl)oxime, 1-phenyl-1,2-propanedione-2-(o-methoxycarbonyl)oxime, l-phenyl-1,2-propanedione-2-(o-ethoxycarbonyl) oxime, l-phenyl-1,2-propanedione-2-(o-benzoyl)oxime, bis(α-isonitrosopropiophenoneoxime)isophthal, 1,2-octanedione, 1-[4-(phenylthio)phenyl]-, 2-(O-benzoyloxime), and ethanone, 1-[9-ethyl-6-(2-methylbenzoyl)-9H-carbazol-3-yl]-, 1-(O-acetyloxime). Examples of the acylphosphine oxides include 2,4,6-trimethylbenzoyldiphenyl-phosphine oxide and bis(2,4,6-trimethylbenzoyl)phenylphosphine oxide.

The photosensitive resin composition according to the present invention further contains a polymerization inhibitor and thus the concentration of excitons is adjusted. This allows an excessive photoresponsive property to be reduced and an exposure margin to be widened. In the photosensitive resin composition according to the present invention, by containing a coloring agent, the action of reducing stray light from the light emission area is exhibited when the photosensitive resin composition is used for the insulating layer of an organic electroluminescent device, and the action of a blinder for hiding a circuit wiring on a circuit board is exhibited when the photosensitive resin composition is used for the solder resist of the circuit board. Examples of the coloring agent include a dye and a pigment. Examples of the dye include thermochromic dyes. Examples of the pigment include inorganic pigments and organic pigments. As such a coloring agent, a coloring agent that is soluble in an organic solvent that dissolves the alkali-soluble polyimide (a) and compatible with the alkali-soluble polyimide (a) is preferable.

The photosensitive resin composition according to the present invention can improve the adhesion to a substrate by containing, for example, a surfactant, a silane coupling agent, and titanium chelating agent. As the organic solvent in the present invention, an organic solvent that can dissolve the photosensitive resin composition is preferable. Examples of such an organic solvent include ethers, acetates, ketones, aromatic hydrocarbons, N-methyl-2-pyrrolidone, N-cyclohexyl-2-pyrrolidone, N,N-dimethylformamide, N,N-dimethylacetamide, dimethylsulfoxide, and γ-butyrolactone. The photosensitive resin composition according to the present invention may include two or more of these solvents as the organic solvent.

Examples of the ethers include ethylene glycol monomethyl ether, ethylene glycol monoethyl ether, propylene glycol monomethyl ether, propylene glycol monoethyl ether, ethylene glycol dimethyl ether, ethylene glycol diethyl ether, and ethylene glycol dibutyl ether. Examples of the acetates include ethylene glycol monoethyl ether acetate, propylene glycol monomethyl ether acetate, propyl acetate, butyl acetate, isobutyl acetate, 3-methoxybutyl acetate, 3-methyl-3-methoxybutyl acetate, methyl lactate, ethyl lactate, and butyl lactate. Examples of the ketones include acetone, methyl ethyl ketone, acetylacetone, methyl propyl ketone, methyl butyl ketone, methyl isobutyl ketone, cyclopentanone, and 2-heptanone. Examples of the aromatic hydrocarbons include alcohols such as butyl alcohol, isobutyl alcohol, pentanol, 4-methyl-2-pentanol, 3-methyl-2-butanol, 3-methyl-3-methoxybutanol, and diacetone alcohol, toluene, and xylene.

<Method for Producing Photosensitive Resin Composition>

The photosensitive resin composition according to the present invention can be obtained by mixing and dissolving the alkali-soluble polyimide (a), the unsaturated bond-containing compound (b), the thermally crosslinkable compound (c), the photopolymerization initiator (d), and other additives, if necessary. The photosensitive resin composition according to the present invention can be dissolved in the organic solvent to provide a solution having a solid content concentration of about 20% by mass to 70% by mass, if necessary.

The photosensitive resin composition according to the present invention may be filtered using a filter paper or a filter. A method for filtering the photosensitive resin composition is not particularly limited and a method for filtering the composition by pressure filtration using a filter having a captured particle diameter of 0.4 μm to 10 μm is preferable.

<Form of Photosensitive Resin Composition>

The form of the photosensitive resin composition according to the present invention is not particularly limited and can be selected as, for example, a film form, a rod from, a sphere form, and a pellet form depending on applications. The “film” described here includes a membrane, a sheet, and a plate. In the present invention, the form of the photosensitive resin composition is preferably the film-like form. In other words, a photosensitive resin composition film prepared by forming the photosensitive resin composition according to the present invention into a film-like product is preferable. For example, the photosensitive resin composition film according to the present invention can be obtained by applying the photosensitive resin composition according to the present invention onto a support and subsequently drying the applied composition, if necessary.

Examples of the support include a polyethylene terephthalate (PET) film, a polyphenylene sulfide film, and a polyimide film. In order to improve adhesion and release properties, the bonded surface between the support and the photosensitive resin composition film may be subjected to surface treatment using a silicone, a silane coupling agent, an aluminum chelating agent, and polyurea. The thickness of the support is not particularly limited and is preferably 10 μm to 100 μm from the viewpoint of workability.

The photosensitive resin composition according to the present invention may have a protective film for protecting the photosensitive resin composition film. This protective film can protect the surface of the photosensitive resin composition film from contaminants such as dirt and dust in the atmosphere.

Examples of the protective film in the present invention include a polyethylene film, a polypropylene (PP) film, a polyester film, and a polyvinyl alcohol film. This protective film preferably has peel strength to the extent that the photosensitive resin composition film and the protective film are not easily peeled off.

Examples of a method for applying the photosensitive resin composition to the support for preparing the photosensitive resin composition film according to the present invention include spin coating using a spinner, spray coating, roll coating, screen printing, and a method of using a blade coater, a die coater, a calendar coater, a meniscus coater, a bar coater, a roll coater, a comma roll coater, a gravure coater, a screen coater, and a slit die coater. The coating thickness of the photosensitive resin composition varies depending on, for example, the coating method, the solid content concentration of the photosensitive resin composition to be applied, and the viscosity. The film thickness after drying of the photosensitive resin composition is preferably controlled so as to be 0.5 μm or more and 100 μm or less.

Examples of the drying apparatus for drying the applied photosensitive resin composition include an oven, a hot plate, and an infrared apparatus. The drying temperature and the drying time may be within a range where the organic solvent can be volatilized and preferably the range where the photosensitive resin composition film becomes in an uncured state or a semi-cure state is appropriately set. Specifically, the drying temperature is preferably within the range of 40° C. to 120° C. and the drying time is preferably within the range of 1 minute to several tens of minutes. The drying temperature may be raised stepwise by combining the temperatures within this range. For example, at the time of drying the photosensitive resin composition, the photosensitive resin composition may be heated at each temperature of 50° C., 60° C., and 70° C. for 1 minute.

<Cured Product of Photosensitive Resin Composition>

Thermal curing of the photosensitive resin composition according to the present invention allows the cured product of this photosensitive resin composition to be obtained. In the thermal curing of the photosensitive resin composition, a thermal curing temperature is preferably in the range of 120° C. to 400° C. The form of the cured product of the photosensitive resin composition is not particularly limited and can be selected as, for example, a film form, a rod from, a sphere form, and a pellet form depending on applications. In the present invention, this cured product is preferably a film-like product. In addition, the pattern processing of the photosensitive resin composition allows the shape of the cured product to be selected in accordance with the application such as forming the protective film on a wall, forming via holes for conduction, adjusting impedance, electrostatic capacitance, or internal stress, and providing a heat dissipation function. The thickness of the cured product (the film formed of the cured product) is preferably 0.5 μm or more and 150 μm or less. An insulating film according to the present invention is formed of the cured product of the photosensitive resin composition according to the present invention.

<Processing Example of Photosensitive Resin Composition Film>

Subsequently, a method for pattern processing the photosensitive resin composition film according to the present invention to form a permanent resist will be described with reference to an example.

First, in the case where the photosensitive resin composition film has a protective film, the protective film is peeled off. The substrate and the photosensitive resin composition film are disposed so as to be opposed to each other and bonded by thermocompression bonding. Examples of the method of the thermocompression bonding include a hot press process, a hot lamination process, and a thermal vacuum lamination process. From the viewpoint of improving adhesion and an embedding property of the photosensitive resin composition film to the substrate, the thermocompression bonding temperature is preferably 40° C. or more. On the other hand, from the viewpoint of reducing excessive curing of the photosensitive resin composition film at the time of thermocompression bonding, the thermocompression bonding temperature is preferably 150° C. or less.

Examples of the substrate include a silicon wafer, ceramics, gallium arsenide, an organic circuit board, an inorganic circuit board, and substrates formed by arranging constitutional materials for the circuit to these substrates. Examples of the organic circuit board include glass substrate copper clad laminates such as a glass cloth-epoxy copper clad laminate, composite copper clad laminates such as a glass non-woven fabric-epoxy copper clad laminate, heat resistant thermoplastic substrates such as a polyetherimide resin substrate, a polyetherketone resin substrate, and a polysulfone resin substrate, and flexible substrates such as a polyester copper clad film substrate and a polyimide copper clad film substrate. Examples of the inorganic circuit board include ceramic substrates such as an alumina substrate, aluminum nitride substrate, and a silicon carbide substrate and metal-based substrates such an aluminum-based substrate and an iron-based substrate. Examples of the constitutional materials for the circuit include electric conductor containing metals such as silver, gold, and copper, resistors containing inorganic oxides or the like, low dielectric materials containing at least one material of glass-based materials, resins, or the like, high dielectric materials containing resins, high dielectric constant inorganic particles, or the like, and insulator containing glass-based materials or the like.

Subsequently, a mask having a desired pattern is formed on the photosensitive resin composition film formed on the substrate by the above method and the photosensitive resin composition film is irradiated with actinic rays through the mask to expose the photosensitive resin composition film in a pattern. Examples of the actinic rays used for the exposure include ultraviolet rays, visible rays, electron rays, and X rays. In the present invention, i-line (365 nm), h-line (405 nm), and g-line (436 nm) of a mercury lamp are preferably used. In the photosensitive resin composition film, in the case where the support is a transparent material with respect to these rays, the photosensitive resin composition film may be subjected to exposure without peeling off the support.

After the exposure of the photosensitive resin composition film, the unexposed part of the photosensitive resin composition film is removed by using a development liquid to form a pattern on the photosensitive resin composition film. Examples of the preferable development liquid include an aqueous solution of tetramethyl ammonium and aqueous solutions of compounds exhibiting alkalinity such as diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, and hexamethylenediamine. To these aqueous alkali solutions, polar solvents such as N-methyl-2-pyrrolidone, N,N-dimethylformamide, N,N-dimethylacetamide, dimethyl sulfoxide, y-butyrolactone, and dimethyl acrylamide, alcohols such as methanol, ethanol, and isopropanol (2-propanol), esters such as ethyl lactate and propylene glycol monomethyl ether acetate, and ketones such as cyclopentanone, cyclohexanone, isobutyl ketone, and methyl isobutyl ketone may be added, if necessary.

Examples of methods for developing the photosensitive resin composition film include a method for spraying the development liquid on the covered film surface, a method for immersing the covered film surface into the development liquid, a method for applying ultrasonic sound while immersing the covered film surface in the development liquid, and a method for spraying the development liquid while rotating the substrate. Here, the “covered film surface” refers to the surface of the substrate part covered by the patterned photosensitive resin composition film in the substrate surface. Conditions such as a development time and a temperature of the development liquid can be set within a range where the unexposed part of the photosensitive resin composition film is removed. In order to process a fine pattern on the photosensitive resin composition film and to remove residues in the spaces of the pattern, the photosensitive resin composition film may be further developed after the unexposed part is removed.

After the development of the photosensitive resin composition film, the substrate may be subjected to rinsing treatment. As a rinsing liquid used in this rinsing treatment, water is preferable. Alcohols such as ethanol and isopropyl alcohol (2-propanol), esters such as ethyl lactate and propylene glycol monomethyl ether acetate and the like may be added into the rinsing liquid (water), if necessary.

In the case where allowable ranges of development conditions, such as an increase in resolution of the pattern during development, are increased, a step of baking treatment of the photosensitive resin composition film before development may be adopted. In this baking treatment, the baking temperature is preferably 50° C. or more and more preferably 60° C. or more. On the other hand, the baking temperature is preferably 180° C. or less and more preferably 120° C. or less. The baking time is preferably 5 seconds to several hours.

After the development of the photosensitive resin composition film, the photosensitive resin composition film on the substrate is subjected to heat treatment at a temperature of 120° C. to 400° C. to form a cured film. The heat treatment (curing) may be carried out by raising the temperature stepwise by selecting temperatures or by continuously raising the temperature by selecting a certain temperature range. In this heat treatment, the heating temperature is more preferably 150° C. or more and further preferably 180° C. or more. On the other hand, the heating temperature is preferably 300° C. or less and more preferably 250° C. or less. The heat treatment time is preferably 5 minutes to 5 hours. Examples of this heat treatment include a method for carrying out the heat treatment at 130° C. and 200° C. for 30 minutes each and a method for linearly raising the temperature from room temperature to 250° C. over 2 hours.

From the viewpoint of heat resistance, the cured film obtained by the above-described heat treatment is preferably a cured film having a high glass transition temperature. In the present invention, the glass transition temperature of the cured film is preferably 180° C. or more, more preferably 220° C. or more, and further preferably 250° C. or more.

In order to obtain a rectangular shape pattern in the thick film made of a photosensitive resin composition film, yellowing is preferably small so that light reaches the bottom part of the photosensitive resin composition film on the substrate. The degree of yellowing can be calculated from the following formula.

Degree of yellowing=Abs(1)/Abs(0)

Abs (0) represents the absorbance of the photosensitive resin composition before exposure at a wavelength of 405 nm. Abs (1) represents the absorbance of the photosensitive resin composition after exposure at a wavelength of 405 nm. The degree of yellowing is preferably less than 1.25 and more preferably less than 1.20.

In addition, in order to obtain the above-described pattern in the thick film, the residual film ratio after curing is preferably high. The residual film ratio is preferably 70% or more and more preferably 85% or more. Here, the residual film ratio refers to the percentage of the thickness after the heat treatment to the film thickness before exposure and development of the photosensitive resin composition and can be calculated from the following formula.

Residual film ratio [%]=(Film thickness after curing/Film thickness before exposure and development)×100

Use of the photosensitive resin composition according to the present invention as the material of the above-described cured film allows the residual film ratio to be controlled in the above range.

<Insulating Film and Electronic Component>

The applications of the photosensitive resin composition, the photosensitive resin composition film, the cured product, and the insulating film according to the present invention are not particularly limited. For example, as described above, the cured product according to the present invention is formed by curing the photosensitive resin composition or the photosensitive resin composition film according to the present invention. The insulating film (cured film) according to the present invention made of such a cured product of the photosensitive resin composition or the photosensitive resin composition film may be applicable to resists (protective films), various electronic components and devices. Examples of the resist to which the insulating film according to the present invention is applied include a surface protective film and an interlayer insulating film incorporated in a substrate or a package for a system using semiconductors such as a mounting substrate and a wafer level package, and a wiring protective insulating film of a circuit board.

The insulating film according to the present invention can be suitably used for, in particular, a permanent resist, that is, an interlayer insulating film on which a pattern is formed and an adhesive application for thermocompression bonding of, for example, a substrate, a glass, or a semiconductor element after pattern formation with an adherend, due to excellent heat resistance of the insulating film.

On the other hand, the electronic component according to the present invention is an electronic component containing the insulating film (the insulating film according to the present invention) made of the above-described cured product of the photosensitive resin composition or the photosensitive resin composition film. In particular, the insulating film according to the present invention can form the pattern in the thick film and thus is suitably used in the roof part of a hollow structure body having a hollow structure. The electronic component according to the present invention preferably contains a hollow structure body having a roof made of such an insulating film. As described above, an increase in the film thickness of the roof part of the hollow structure body with the insulating film allows the drop in the roof of the hollow structure body to be prevented. As a result, the retention of the hollow structure in the electronic component according to the present invention can be improved.

### EXAMPLES

Hereinafter, the present invention will be specifically described with reference to Examples and Comparative Examples. However, it is needless to say that the present invention is not limited to each of Examples described below. The alkali-soluble polyimide (a) and the photopolymerization initiator (d) used in each of Examples and Comparative Examples below were synthesized by the following method.

### Synthesis Example 1

The synthesis method of Polyimide A1 acting as the alkali-soluble polyimide (a) in Synthesis Example 1 in the present invention will be described. In the synthesis method of Polyimide A1, 2,2-bis(3-amino-4-hydroxyphenyl)hexafluoropropane (32.78 g (0.0895 mol)) and 1,3-bis(3-aminopropyl)tetramethyldisiloxane (1.24 g (0.005 mol)) were dissolved in N methyl-2-pyrrolidone (100 g) under a dry nitrogen gas stream. Hereinafter, “N-methyl-2-pyrrolidone” is referred to as “NMP”. To this solution, bis-(3-phthalyl anhydride) ether (31.02 g (0.10 mol)) was added together with NMP (30 g) and the resultant solution was stirred at 20° C. for 1 hour and then stirred at 50° C. for 4 hours. To the solution after the stirring, 3-aminophenol (1.09 g (0.01 mol)) was added and the resultant solution was stirred at 50° C. for 2 hours and thereafter stirred at 180° C. for 5 hours to give a resin solution. Subsequently, the resin solution was poured into water (3 L) to generate a white precipitate. The white precipitate was collected by filtration and washed 3 times with water and thereafter the washed white precipitate was dried at 80° C. for 5 hours in a vacuum dryer. As a result, the powder of the alkali-soluble polyimide having the structure represented by the general formula (2) (Polyimide A1) was obtained.

The imidation ratio of the obtained Polyimide A1 was 94%. In addition, the solubility of Polyimide A1 into an aqueous solution of tetramethyl ammonium (2.38 wt %) at 23° C. was 0.5 g/100 g or more.

### Synthesis Example 2

The synthesis method of Polyimide A2 acting as the alkali-soluble polyimide (a) in Synthesis Example 2 in the present invention will be described. The synthesis method of Polyimide A2 is the same as the method in Synthesis Example 1 except that the heating and stirring conditions after addition of 3-aminophenol was changed from at 50° C. for 2 hours and at 180° C. for 5 hours to 50° C. for 2 hours and at 160° C. for 5 hours. As a result, the powder of the alkali-soluble polyimide having the structure represented by the general formula (2) (Polyimide A2) was obtained. The imidation ratio of the obtained Polyimide A2 was 76%. In addition, the solubility of Polyimide A2 into an aqueous solution of tetramethyl ammonium (2.38 wt %) at 23° C. was 0.5 g/100 g or more.

### Synthesis Example 3

The synthesis method of Polyimide A3 acting as the alkali-soluble polyimide (a) in Synthesis Example 3 in the present invention will be described. In the synthesis method of polyimide A3, 4,4′-diaminodiphenyl ether (18.0 g (0.09 mol)) was dissolved in NMP (100 g) under a dry nitrogen gas stream. To this solution, bis-(3-phthalyl anhydride) ether (31.02 g (0.10 mol)) was added together with NMP (30 g) and the resultant solution was stirred at 20° C. for 1 hour and then stirred at 50° C. for 4 hours. The solution after the stirring was further stirred at 180° C. for 5 hours to give a resin solution. Subsequently, the resin solution was poured into water (3 L) to generate a white precipitate. The white precipitate was collected by filtration and washed 3 times with water and thereafter the washed white precipitate was dried at 80° C. for 5 hours in a vacuum dryer. As a result, the powder of the alkali-soluble polyimide not having the structure represented by the general formula (2) or the general formula (3) and the siloxane structure (Polyimide A3) was obtained.

The imidation ratio of the obtained Polyimide A3 was 95%. In addition, the solubility of Polyimide A3 into an aqueous solution of tetramethyl ammonium (2.38% by mass) at 23° C. was 0.5 g/100 g or more.

### Synthesis Example 4

The synthesis method of Polyimide A4 acting as the alkali-soluble polyimide (a) in Synthesis Example 4 in the present invention will be described. In the synthesis method of Polyimide A4, 2,2-bis(3-amino-4-hydroxyphenyl)hexafluoropropane (32.96 g (0.09 mol)) was dissolved in NMP (100 g) under a dry nitrogen gas stream. To this solution, bis-(3-phthalyl anhydride) ether (31.02 g (0.10 mol)) was added together with NMP (30 g) and the resultant solution was stirred at 20° C. for 1 hour and then stirred at 50° C. for 4 hours. To the solution after the stirring, 3-aminophenol (1.09 g (0.01 mol)) was added and the resultant solution was stirred at 50° C. for 2 hours and thereafter stirred at 180° C. for 5 hours to give a resin solution. Subsequently, the resin solution was poured into water (3 L) to generate a white precipitate. The white precipitate was collected by filtration and washed 3 times with water and thereafter the washed white precipitate was dried at 80° C. for 5 hours in a vacuum dryer. As a result, the powder of the alkali-soluble polyimide having the structure represented by the general formula (2) and not having the siloxane structure (Polyimide A4) was obtained.

The imidation ratio of the obtained Polyimide A4 was 95%. In addition, the solubility of Polyimide A4 into an aqueous solution of tetramethyl ammonium (2.38% by mass) at 23° C. was 0.5 g/100 g or more.

### Synthesis Example 5

The synthesis method of Polyimide A5 acting as the alkali-soluble polyimide (a) in Synthesis Example 5 in the present invention will be described. In the synthesis method of Polyimide A5, 2,2-bis(3-amino-4-hydroxyphenyl)hexafluoropropane (32.41 g (0.0885 mol)) and 1,3-bis(3-aminopropyl)tetramethyldisiloxane (3.72 g (0.015 mol)) were dissolved in NMP (100 g) under a dry nitrogen gas stream. To this solution, bis-(3-phthalyl anhydride) ether (31.02 g (0.10 mol)) was added together with NMP (30 g), and the resultant solution was stirred at 20° C. for 1 hour and then stirred at 50° C. for 4 hours. To the solution after the stirring, 3-aminophenol (1.09 g (0.01 mol)) was added and the resultant solution was stirred at 50° C. for 2 hours and thereafter stirred at 180° C. for 5 hours to give a resin solution. Subsequently, the resin solution was poured into water (3 L) to generate a white precipitate. The white precipitate was collected by filtration and washed 3 times with water and thereafter the washed white precipitate was dried at 80° C. for 5 hours in a vacuum dryer. As a result, the powder of the alkali-soluble polyimide having the structure represented by the general formula (2) (Polyimide A5) was obtained.

The imidation ratio of the obtained Polyimide A5 was 95%. In addition, the solubility of Polyimide A5 into an aqueous solution of tetramethyl ammonium (2.38% by mass) at 23° C. was 0.5 g/100 g or more.

### Synthesis Example 6

The synthesis method of Photopolymerization Initiator B1 acting as the photopolymerization initiator (d) in Synthesis Example 6 in the present invention will be described. In the synthesis method of Photopolymerization Initiator B1, a diphenyl sulfide solution (9.31 g) cooled to 0° C. was added to aluminum chloride (7.36 g) in dichloromethane (50 mL). Then, to this mixture, chloroacetyl chloride (5.56 g) was added and the resultant mixture was stirred at room temperature for 2 hours. To the obtained reaction mixture, aluminum chloride (7.33 g) and n-butyryl chloride (5.59 g) were added at 0° C. and the mixture was stirred overnight. The reaction mixture after the reaction was poured into ice water and the organic phase was extracted with dichloromethane. The extracted liquid was dried over magnesium sulfide and concentrated. The resultant residue was purified with column chromatography. As a result, 10.35 g of Intermediate Compound Q1 having the following structure was obtained.

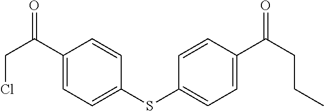 [SMILES: CCCC(=O)c1ccc(Sc2ccc(C(=O)CCl)cc2)cc1]

Intermediate Compound Q1 (1.0 g) was dissolved in acetone (30 mL) and potassium carbonate (1.11 g) and salicylaldehyde (0.73 g) were added to the solution. The resultant mixture was heated to reflux and stirred for 3 hours. The reaction mixture was cooled to room temperature and acidified by adding hydrochloric acid after water was added. Thus generated precipitate was filtered with a filter and dried. As a result, 1.0 g of Intermediate Compound Q2 having the following structure was obtained.

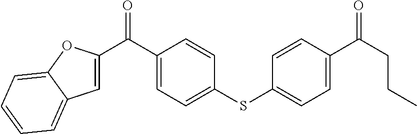 [SMILES: CCCC(=O)c1ccc(Sc2ccc(C(=O)c3cc4ccccc4o3)cc2)cc1]

This Intermediate Compound Q2 (1.0 g) was dissolved in ethyl acetate (10 mL) and hydroxyammonium chloride and (0.35 g) and pyridine (5 mL) were added to the resultant solution. The obtained mixture was heated to reflux and stirred for 3 hours. The reaction mixture was cooled to room temperature and poured into water, and the organic phase was extracted with ethyl acetate and thereafter dried over magnesium sulfate. After concentrating the organic phase after drying, the residue was purified by column chromatography. As a result, 283 mg of Intermediate Compound Q3 having the following structure was obtained.

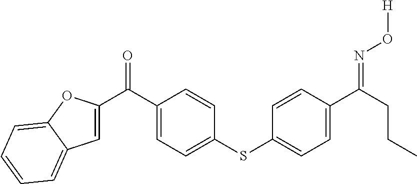 [SMILES: CCC/C(=N\O)c1ccc(Sc2ccc(C(=O)c3cc4ccccc4o3)cc2)cc1]

Intermediate Compound Q3 (283 mg) was dissolved in ethyl acetate (14 mL) and acetyl chloride and (78.5 mg) and triethylamine (111 mg) were added to the resultant solution. The resultant mixture was stirred at room temperature for 3 hours. The reaction mixture was poured into water and the organic phase was extracted with ethyl acetate. After concentrating the extracted organic phase, the resultant residue was purified by column chromatography. As a result, Photopolymerization Initiator B1 (226 mg) having the following structure included in the general formula (1-2) was obtained.

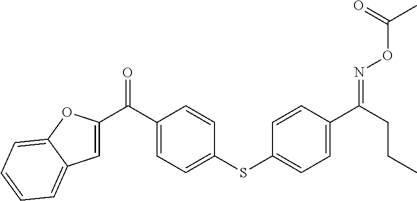

### Synthesis Example 7

The synthesis method of Photopolymerization Initiator B2 acting as the photopolymerization initiator (d) in Synthesis Example 7 in the present invention will be described. The synthesis method of Photopolymerization Initiator B2 is the same as the method in Photopolymerization Initiator B1 (Synthesis Example 6) except that 4-methyl-pentanoic acid chloride was added instead of n-butyryl chloride. As a result, Photopolymerization Initiator B2 having the following structure was obtained.

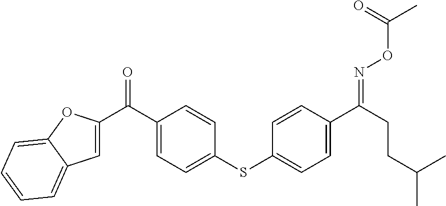 [SMILES: CC(=O)O/N=C(\CCC(C)C)c1ccc(Sc2ccc(C(=O)c3cc4ccccc4o3)cc2)cc1]

(Other Materials)

Furthermore, each of the other materials used in each of Examples and Comparative Examples is as described below.

As the unsaturated bond-containing compounds (b), DPE-6A (trade name, manufactured by Kyoeisha Chemical Co., Ltd., dipentaerythritol hexaacrylate) and BP-6EM (trade name, manufactured by Kyoeisha Chemical Co., Ltd., ethylene oxide-modified bisphenol A dimethacrylate) were used.

As the thermally crosslinkable compound (c), HMOM-TPHAP (trade name, manufactured by Honshu Chemical Industry Co., Ltd., 4,4′,4″-ethylidynetris[2,6-bis(methoxymethyl)phenol]) was used.

As the photopolymerization initiator (d), NCI-930 (trade name, manufactured by ADEKA Corporation) was used. As the photopolymerization initiator other than the photopolymerization initiator (d), that is, as the other photopolymerization initiator (d′), N-1919 (trade name, manufactured by ADEKA Corporation), NCI-831 (trade name, manufactured by ADEKA Corporation), “IRGACURE” (registered trademark) OXE01 (trade name, manufactured by BASF SE., 1,2-octanedione, 1-[4-(phenylthio)phenyl]-, 2-(o-benzoyloxime)), “IRGACURE” OXE02 (trade name, manufactured by BASF SE., ethanone, 1-[9-ethyl-6-(2-methylbenzoyl)-9H-carbazol-3-yl]-, 1-(O-acetyloxime)), and “IRGACURE” 819 (trade name, manufactured by BASF SE., bis(2,4,6-trimethylbenzoyl)phenylphosphine oxide) were used.

In addition, in each of Examples and Comparative Examples below, other additives (e) were a polymerization inhibitor and a silane coupling agent. As the polymerization inhibitor, QS-30 (trade name, manufactured by Kawasaki Kasei Chemicals Ltd., 4-methoxy-1-naphthol) was used. As the silane coupling agent, IM-1000 (trade name, manufactured by JX Nippon Mining & Metals Corporation) was used.

In addition, evaluation methods in each of Examples and Comparative Examples below are as described below.

<Resolution>

The protective film of the photosensitive resin composition film obtained in each of Examples and Comparative Examples was peeled off. Using a laminating apparatus (manufactured by Takatori Corporation, VTM-200M), a released surface of the photosensitive resin composition film was laminated on a 4-inch silicon wafer under conditions of a stage temperature of 80° C., a roll temperature of 80° C., a degree of vacuum of 150 Pa, an attaching speed of 5 mm/sec, and an attaching pressure of 0.3 MPa. For Examples 1 to 13 and Comparative Examples 1 to 5, photosensitive resin composition layers having a thickness of 40 μm were formed on the silicon wafers by this method. For Examples 14 and 15 and Comparative Examples 6 and 7, the support film of the photosensitive resin composition film on a silicon wafer was peeled off and the protective film of one piece of the prepared photosensitive resin composition film was further peeled off to laminate this prepared photosensitive resin composition film on the released surface (the surface from which the support film was peeled off) of the photosensitive resin composition film on the silicon wafer under the same conditions as described above. This allowed a photosensitive resin composition layer having the total thickness of 80 μm to be formed on the silicon wafer.

After peeling the support film of the photosensitive resin composition layer, a photomask having a pattern of Line (L)/Space (S)=5/5, 10/10, 15/15, 20/20, 25/25, 30/30, 35 35, 40/40, 45/45, 50/50, 60/60, 70/70, 80/80, 90/90, and 100/100 (unit, μm) was set in an exposure apparatus (manufactured by Seiwa optical Co., Ltd., SME-150GA-TRJ) so that the exposure gap was 10 μm and the photosensitive resin composition layer was exposed with light transmitted through the LU0385 filter in an ultra-high pressure mercury lamp. The exposure amount of the transmitted light was determined to be 800 mJ/cm² (in terms of h line) in Examples 1 to 13 and Comparative Examples 1 to 5 and to be 1,600 mJ/cm² (in terms of h line) in Examples 14 and 15 and Comparative Examples 6 and 7.

After exposure, the photosensitive resin composition layer was heated on a hot plate at 100° C. for 5 minutes. Subsequently, the paddle development was carried out using a 2.38% by mass aqueous solution of tetramethylammonium hydroxide, whereby the unexposed part of the photosensitive resin composition layer was removed. The development time of the paddle development was determined to be for 180 seconds in Examples 1 to 13 and Comparative Examples 1 to 5 and to be for 360 seconds in Examples 14 and 15 and Comparative Examples 6 and 7.

Subsequently, the developed layer was rinsed with water for 60 seconds. Thereafter, spin-drying was carried out to give a pattern on the photosensitive resin composition layer. Using an inert oven, after raising the temperature from 60° C. to 200° C. over 1 hour, the photosensitive resin composition layer was cured at 200° C. for 1 hour under a nitrogen gas stream (an oxygen concentration of 20 ppm or less). The silicon wafer was taken out from the inert oven when the temperature of the photosensitive resin composition layer after curing reached 50° C. or less. The pattern formed on the photosensitive resin composition layer on the silicon wafer was observed using a microscope. In the evaluation of the resolution of Examples and Comparative Example, the case where the line and space of a minimum dimension that was open in the observed pattern is 40 μm or less was evaluated to be excellent “⊚”, the case where the above-described line and space is 45 μm or more and 100 m or less was evaluated to be good “◯”, and the case where the pattern had no opening was evaluated to be poor “x”.

<Pattern Shape>

For line and space pattern obtained by the same method as the method in the case of the above-described evaluation of the resolution, the silicon wafer was cut so as to be perpendicular to the line pattern to expose the section. Using an optical microscope, the patterned section of L/S=100/100 μm was observed to evaluate the sectional shape of the pattern at a magnification of 200 times. In the evaluation of the patterns in Examples and Comparative Examples, a taper angle between the surface (substrate surface) of the silicon wafer and the pattern side surface was measured. In the case where the taper angle was 90° or less and 85° or more was evaluated to be excellent “⊚”, the case where a taper angle was less than 85° and 80° or more was evaluated to be good “◯”, and the case where the taper angle was less than 80° was evaluated to be acceptable “Δ”. In addition, in the evaluation of the pattern shape, the case where the sectional shape of the pattern was inversely tapered shape forming a taper angle of more than 90° was evaluated as to be the first defect “x” and the case where the sectional shape of the pattern had a shape having a constricted shape was evaluated to be the second defect “xx”.

<Thick Film Processability (Residual Film Ratio)>

The thickness of the obtained photosensitive resin composition film after laminating obtained by the same method as the method in the case of above-described evaluation of the resolution was measured and this measured value was determined to be “Film thickness before exposure and development”. In addition, for the sample of the line and space pattern after curing obtained by the same method as the method in the case of the above-described evaluation of the resolution, the film thickness of the line pattern of L/S=100/100 μm was measured and this measured value was determined to be “Film thickness after curing”. In the evaluation of the thick film processability in Examples and Comparative Examples, the residual film ratio was calculated in accordance with the following formula and the thick film processability of the photosensitive resin composition film was evaluated based on the obtained residual film ratio.

Residual film ratio [%]=(Film thickness after curing/Film thickness before exposure and development)×100

Specifically, the case where the residual film ratio was 85% or more was evaluated to be excellent “⊚”, the case where the residual film ratio was less than 85% and 70% or more was evaluated to be good “◯”, and the case where the residual film ratio was less than 70% was evaluated to be poor “x”.

<Moisture Resistance and Adhesion>

The photosensitive resin composition was processed in the same method as the method in the case of the above-described evaluation of the resolution except that the photomask was not used and that the photosensitive resin composition was entirely exposed. By this process, the cured film of the photosensitive resin composition was prepared. In the obtained cured film, a grid-like cut having 10 rows and 10 columns was prepared at intervals of 1 mm using a cutter. This allowed a total of 100 pieces of partition part (hereinafter referred to as squares) in this cured film to be formed. Subsequently, using a pressure cooker test (PCT) apparatus, this cured film was subjected to PCT treatment at saturated conditions of 121° C. and 2 atm for 200 hours. Thereafter, among the 100 squares in the cured film, the number of the squares that were peeled off from the silicon wafer by peeling using “Sellotape” (registered trademark) was counted. On the basis of the counting result, the moisture resistance and adhesion of the photosensitive resin composition were evaluated. In the evaluation of the moisture resistance and adhesion in Examples and Comparative Examples, the case where the number of squares remaining on the silicon wafer (the remaining number) was 100 squares in the 100 squares was evaluated to be excellent “⊚”, the case where the remaining number was 99 to 80 was evaluated to be good “◯”, and the case where the remaining number was 79 to 0 was evaluated to be poor “x”.

<Heat Resistance (5%-Weight Loss Temperature Measurement>

The photosensitive resin composition was processed in the same method as the method in the case of the above-described evaluation of the resolution except that the photomask was not used and that the photosensitive resin composition was entirely exposed. By this process, the cured film of the photosensitive resin composition was prepared. The obtained cured film was peeled off from the silicon wafer to prepare a single film. The glass transition temperature of the single film of the prepared cured film was measured with a dynamic viscoelasticity measuring apparatus (manufactured by Hitachi High-Tech Science Corporation, DMS6100). Here, this measurement was carried out under conditions of Test mode: Tensile, Test temperature: Room temperature (25° C.) to 350° C., Temperature rising rate: 5° C./min, Test frequency: 1 Hz, Chuck distance: 10 mm, and Sample width: 5 mm. The heat resistances in Examples and Comparative Examples were evaluated on the basis of thus measured glass transition temperatures of the single films (cured films) and thus the obtained glass transition temperatures [° C.] were determined to be the evaluated results.

<Degree of Yellowing>

The protective film of the photosensitive resin composition film obtained in each of Examples and Comparative Examples was peeled off and the absorbance Abs(0) of this photosensitive resin composition film before exposure was measured at a wavelength of 405 nm with a spectrophotometer (manufactured by Hitachi High-Tech Science Corporation, U-3900) using the base film as the reference. Subsequently, the protective film of a newly prepared photosensitive resin composition film was peeled off and thereafter this photosensitive resin composition film was exposed to transmitted light through the LU0385 filter in an ultra-high pressure mercury lamp at an exposure amount of 800 mJ/cm² (in terms of h-line). Then, the absorbance Abs(1) of this photosensitive resin composition film after exposure was measured at a wavelength of 405 nm with the spectrophotometer (manufactured by Hitachi High-Tech Science Corporation, U-3900) using the base film as the reference. Thus obtained Abs(0) and Abs(1) were substituted into the following formula. On the basis of the calculated results, degrees of yellowing in Examples and Comparative Examples were evaluated.

Degree of yellowing=Abs(1)/Abs(0)

For the degrees of yellowing in Examples 14 and 15 and Comparative Examples 6 and 7, the values in Example 2 and 3 and Comparative Examples 2 and 3 having the same compositions as Examples 14 and 15 and Comparative Examples 6 and 7 were used, respectively.

### Example 1

In Example 1 of the present invention, Polyimide A1 of Synthesis Example 1 was used as the alkali-soluble polyimide (a), DPE-6A and BP-6EM were used as the unsaturated bond-containing compounds (b), HMOM-TPHAP was used as the thermally crosslinkable compound (c), and NCI-930 was used as the photopolymerization initiator (d). In addition, QS-30 was used as the polymerization inhibitor and IM-1000 was used as the silane coupling agent.

Specifically, Polyimide A1 (35 g), DPE-6A (2 g), BP-6EM (18 g), HMOM-TPHAP (6 g), NCI-930 (1 g), QS-30 (0.015 g), and IM-1000 (1 g) were dissolved in a mixed solvent of diacetone alcohol/ethyl lactate=40/60 (mass ratio). The amount to be added of the mixed solvent was adjusted so that the solid content concentration was 45% by mass when the additives other than the solvent were determined to be the solid content. The obtained solution was filtered under pressure through a filter having a captured particle diameter of 2 m to give a photosensitive resin composition.

The obtained photosensitive resin composition was applied on a support film (a PET film having a thickness of 50 μm) using a comma roll coater. The applied composition was dried at 85° C. for 13 minutes and thereafter a PP film having a thickness of 50 μm was laminated as a protective film. As a result, a photosensitive resin composition film having a thickness of 40 μm was obtained. The resolution, the pattern shape, the thick film processability and the moisture resistance were evaluated by the above-described methods using the obtained photosensitive resin composition film. Evaluation results of Example 1 are listed in Table 1-1 below.

### Examples 2 to 15 and Comparative Examples 1 to 7

In Examples 2 to 15 and Comparative Examples 1 to 7 comparative to the present invention, the photosensitive resin composition films were prepared by processing according to the method being the same as the method in Example 1 except that the composition in Example 1 described above was changed to the compositions listed in Tables 1-1 and 1-2. The resolution, the pattern shape, the thick film processability, and the moisture resistance were evaluated by the above-described methods using the obtained photosensitive resin composition films. The evaluation results of Examples 2 to 15 are listed in Table 1-1 and the evaluation results of Comparative Examples 1 to 7 are listed in Table 1-2.

TABLE 1-1

| | | Examples | | | | | | | | | | | | | | |
|---|---|---|---|---|---|---|---|---|---|---|---|---|---|---|---|---|
| | | 1 | 2 | 3 | 4 | 5 | 6 | 7 | 8 | 9 | 10 | 11 | 12 | 13 | 14 | 15 |
| Added amount of alkali- | Polyimide A1 | 35 | 35 | 35 | 35 | 35 | — | — | — | — | — | 35 | 35 | 35 | 35 | 35 |
| soluble polyimide (a) | Polyimide A2 | — | — | — | — | — | 35 | 35 | — | — | — | — | — | — | — | — |
| [g] | Polyimide A3 | — | — | — | — | — | — | — | 35 | — | — | — | — | — | — | — |
| | Polyimide A4 | — | — | — | — | — | — | — | — | 35 | — | — | — | — | — | — |
| | Polyimide A5 | — | — | — | — | — | — | — | — | — | 35 | — | — | — | — | — |
| Added amount of | DPE-6A | 2 | 2 | 2 | 2 | 2 | 2 | 2 | 2 | 2 | 2 | 2 | 2 | 2 | 2 | 2 |
| unsaturated bond- | BP-6EM | 18 | 18 | 18 | 18 | 18 | 18 | 18 | 18 | 18 | 18 | 18 | 18 | 18 | 18 | 18 |
| containing compound | | | | | | | | | | | | | | | | |
| (b) [g] | | | | | | | | | | | | | | | | |
| Added amount of | HMOM-TPHAP | 6 | 6 | 6 | 6 | 6 | 6 | 6 | 6 | 6 | 6 | 6 | 6 | 6 | 6 | 6 |
| thermally crosslinkable | | | | | | | | | | | | | | | | |
| compound (c) [g] | | | | | | | | | | | | | | | | |
| Added amount of | NCI-930 | 1 | 1.5 | 3 | 5 | 10 | 3 | 5 | 3 | 3 | 3 | — | — | — | 3 | 5 |
| photopolymerization | Photopolymerization | — | — | — | — | — | — | — | — | — | — | 3 | — | — | — | — |
| initiator (d) [g] | initiator B1 | | | | | | | | | | | | | | | |
| | Photopolymerization | — | — | — | — | — | — | — | — | — | — | — | 1.5 | 3 | — | — |
| | initiator B2 | | | | | | | | | | | | | | | |
| Added amount of other | N-1919 | — | — | — | — | — | — | — | — | — | — | — | — | — | — | — |
| photopolymerization | NCI-831 | — | — | — | — | — | — | — | — | — | — | — | — | — | — | — |
| initiator (d′) [g] | IRGACURE OXE01 | — | — | — | — | — | — | — | — | — | — | — | — | — | — | — |
| | IRGACURE OXE02 | — | — | — | — | — | — | — | — | — | — | — | — | — | — | — |
| | IRGACURE 819 | — | — | — | — | — | — | — | — | — | — | — | — | — | — | — |
| Added amount of | QS-30 | 0.015 | 0.015 | 0.015 | 0.015 | 0.015 | 0.015 | 0.015 | 0.015 | 0.015 | 0.015 | 0.015 | 0.015 | 0.015 | 0.015 | 0.015 |
| polymerization inhibitor | | | | | | | | | | | | | | | | |
| [g] | | | | | | | | | | | | | | | | |
| Added amount of silane | IM-1000 | 1 | 1 | 1 | 1 | 1 | 1 | 1 | 1 | 1 | 1 | 1 | 1 | 1 | 1 | 1 |
| coupling agent [g] | | | | | | | | | | | | | | | | |
| Film thickness before exposure and development [μm] | | 40 | | | | | | | | | | | | | 80 | |
| Resolution | L/S [μm] | 20 | 20 | 20 | 30 | 45 | 20 | 30 | 80 | 25 | 30 | 25 | 20 | 25 | 30 | 40 |
| | Evaluation result | ⊚ | ⊚ | ⊚ | ⊚ | ◯ | ⊚ | ⊚ | ◯ | ⊚ | ⊚ | ⊚ | ⊚ | ⊚ | ⊚ | ⊚ |
| Pattern shape | Cone angle [°] | 86 | 88 | 90 | 89 | 84 | 86 | 88 | 83 | 89 | 86 | 88 | 89 | 88 | 89 | 90 |
| | Evaluation result | ⊚ | ⊚ | ⊚ | ⊚ | ◯ | ⊚ | ⊚ | ◯ | ⊚ | ⊚ | ⊚ | ⊚ | ⊚ | ⊚ | ⊚ |
| Thick film | Residual film ratio [%] | 78 | 81 | 85 | 87 | 90 | 74 | 76 | 89 | 85 | 90 | 87 | 87 | 88 | 91 | 93 |
| processability (residual | Evaluation result | ◯ | ⊚ | ⊚ | ⊚ | ⊚ | ◯ | ◯ | ⊚ | ⊚ | ⊚ | ⊚ | ⊚ | ⊚ | ⊚ | ⊚ |
| film ratio) | | | | | | | | | | | | | | | | |
| Moisture resistance and | Number of peeled squares | 0 | 0 | 0 | 0 | 0 | 17 | 15 | 0 | 6 | 0 | 0 | 0 | 0 | 0 | 0 |
| adhesion | Evaluation result | ⊚ | ⊚ | ⊚ | ⊚ | ⊚ | ◯ | ◯ | ⊚ | ◯ | ⊚ | ⊚ | ⊚ | ⊚ | ⊚ | ⊚ |
| Degree of yellowing | Abs(1)/Abs(0) | 1.04 | 1.04 | 1.03 | 1.05 | 1.06 | 1.04 | 1.04 | 1.03 | 1.04 | 1.04 | 1.18 | 1.18 | 1.18 | 1.03 | 1.05 |
| Heat resistance | Glass transition temperature [° C.] | 252 | 254 | 252 | 251 | 254 | 202 | 203 | 250 | 260 | 219 | 255 | 253 | 252 | 253 | 254 |

TABLE 1-2

| | | Comparative Example | | | | | | |
|---|---|---|---|---|---|---|---|---|
| | | 1 | 2 | 3 | 4 | 5 | 6 | 7 |
| Added amount of | Polyimide A1 | 35 | 35 | 35 | 35 | 35 | 35 | 35 |
| alkali-soluble | Polyimide A2 | — | — | — | — | — | — | — |
| polyimide (a) [g] | Polyimide A3 | — | — | — | — | — | — | — |
| | Polyimide A4 | — | — | — | — | — | — | — |
| | Polyimide A5 | — | — | — | — | — | — | — |
| Added amount of unsaturated bond- | DPE-6A | 2 | 2 | 2 | 2 | 2 | 2 | 2 |
| containing compound (b) [g] | BP-6EM | 18 | 18 | 18 | 18 | 18 | 18 | 18 |
| Added amount of thermally | HMOM-TPHAP | 6 | 6 | 6 | 6 | 6 | 6 | 6 |
| crosslinkable compound (c) [g] | | | | | | | | |
| Added amount of | NCI-930 | — | — | — | — | — | — | — |
| photopolymerization | Photopolymerization | — | — | — | — | — | — | — |
| initiator (d) [g] | initiator B1 | | | | | | | |
| | Photopolymerization | — | — | — | — | — | — | — |
| | initiator B2 | | | | | | | |
| Added amount of other | N-1919 | 3 | — | — | — | — | — | — |
| photopolymerization | NCI-831 | — | 3 | — | — | — | 3 | — |
| initiator (d′) [g] | IRGACURE OXE01 | — | — | 3 | — | — | — | 3 |
| | IRGACURE OXE02 | — | — | — | 3 | — | — | — |
| | IRGACURE 819 | — | — | — | — | 3 | — | — |
| Added amount of polymerization | QS-30 | 0.015 | 0.015 | 0.015 | 0.015 | 0.015 | 0.015 | 0.015 |
| inhibitor [g] | | | | | | | | |
| Added amount of silane coupling | IM-1000 | 1 | 1 | 1 | 1 | 1 | 1 | 1 |
| agent [g] | | | | | | | | |
| Film thickness before exposure and development [μm] | | 40 | | | | | 80 | |
| Resolution | L/S [μm] | 30 | 25 | 20 | 25 | 50 | 40 | 30 |
| | Evaluation result | ⊚ | ⊚ | ⊚ | ⊚ | ◯ | ⊚ | ⊚ |
| Pattern shape | Cone angle [°] | 115 | — | — | 109 | 63 | — | — |
| | Evaluation result | x | xx | xx | x | Δ | xx | xx |
| Thick film processability | Residual film ratio [%] | 85 | 87 | 78 | 86 | 54 | 89 | 84 |
| (residual film ratio) | Evaluation result | ⊚ | ⊚ | ◯ | ⊚ | x | ⊚ | ◯ |
| Moisture resistance | Number of peeled squares | 0 | 0 | 0 | 0 | 0 | 0 | 0 |
| and adhesion | Evaluation result | ⊚ | ⊚ | ⊚ | ⊚ | ⊚ | ⊚ | ⊚ |
| Degree of yellowing | Abs(1)/Abs(0) | 1.33 | 1.27 | 1.05 | 1.35 | 0.92 | 1.27 | 1.05 |
| Heat resistance | Glass transition temperature [° C.] | 250 | 256 | 254 | 254 | 251 | 255 | 252 |

As listed in Table 1-1, Examples 1 to 15 in which the photopolymerization initiators (d) having the structure represented by the above-described general formula (1) are used provide each of the good or better (good or excellent) evaluation results of the pattern shape and the thick film processability. On the other hand, as listed in Table 1-2, Comparative Examples 1 to 7 in which other photopolymerization initiators (d′) are used provide worse results of the pattern shape or the thick film processability than those of Examples 1 to 15.

### Reference Example

In this Reference Example, the photosensitive resin composition film was obtained by the same method as the method in Example 1 except that the photosensitive resin composition in Example 1 was replaced with a mixture of “Photoneece” (registered trademark) UR-5100FX (tradename, manufactured by Toray Industries, Inc.) acting as a polyimide precursor resin composition and γ-butyrolactone (specifically, a mixture of UR-5100FX (200 g) and γ-butyrolactone (100 g)).

Using the obtained photosensitive resin composition film, the resolution, the pattern shape, the thick film processability, and moisture resistance were evaluated by the same method as the method in Example 1. As a result, in Reference Example, the resolution was good “◯”, the pattern shape was acceptable “Δ”, the thick film processability was poor “x”, and the moisture resistance and adhesion were excellent “⊚”. Here, in this Reference Example, DV-605 (trade name, manufactured by Toray Industries, Inc.) was used as the development liquid and the development time was 360 seconds. The curing was carried out at 140° C. for 1 hour and thereafter further carried out at 350° C. for 1 hour.

### INDUSTRIAL APPLICABILITY

The photosensitive resin composition and the photosensitive resin composition film according to the present invention are suitable for a photosensitive resin composition and a photosensitive resin composition film that do not require heat treatment at high temperature and that allow the pattern shape to be processed in a rectangular shape even in a thick film processing. The insulating film obtained from the photosensitive resin composition or the insulating film obtained from the photosensitive resin composition film according to the present invention has excellent electrical properties, mechanical properties, and heat resistance and thus is useful for applications such as a surface protective film and an interlayer insulating film of a semiconductor element, and a wire protective insulating film of a circuit board. In particular, the insulating film according to the present invention can form the pattern in the thick film and thus is suitably used in the roof part of an electronic component having a hollow structure body having a hollow structure.

1. A photosensitive resin composition comprising: an alkali-soluble polyimide (a), an unsaturated bond-containing compound (b), a thermally crosslinkable compound (c), and a photopolymerization initiator (d) having a structure represented by the following general formula (1): 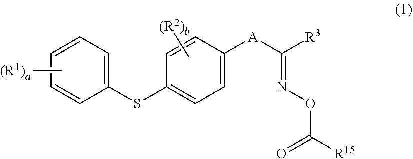
in the general formula (1), R¹ to R³ each independently represents a halogen atom, a hydroxy group, a carboxy group, a nitro group, a cyano group, —NR¹³R¹⁴, a monovalent hydrocarbon group having a carbon number of 1 to 20, an acyl group having a carbon number of 1 to 20, or an alkoxy group having a carbon number of 1 to 20; R¹³ and R¹⁴ each independently represents a hydrogen atom or an alkyl group having a carbon number of 1 to 10; at least some of the hydrogen atoms in the hydrocarbon group, the acyl group, and the alkoxy group are optionally substituted with halogen atoms, hydroxy groups, carboxy groups, nitro groups, cyano groups, or —NR¹³R¹⁴s; the hydrocarbon group and the hydrocarbon group in the alkoxy group are optionally divided by an ether bond, a thioether bond, an ester bond, a thioester bond, an amide bond, or a urethane bond; R¹⁵ represents an alkyl group having a carbon number of 1 to 5; a represents an integer of 0 to 5 and b represents an integer of 0 to 4; and A represents CO or a direct bond.

2. The photosensitive resin composition according to claim 1, wherein the photopolymerization initiator (d) has a structure represented by the following general formula (1-1): 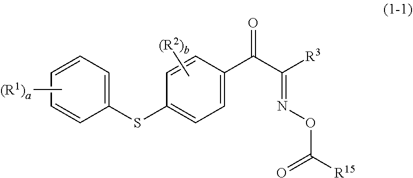
in the general formula (1-1), R¹ to R³ each independently represents a halogen atom, a hydroxy group, a carboxy group, a nitro group, a cyano group, —NR¹³R¹⁴, a monovalent hydrocarbon group having a carbon number of 1 to 20, an acyl group having a carbon number of 1 to 20, or an alkoxy group having a carbon number of 1 to 20; R¹³ and R¹⁴ each independently represents a hydrogen atom or an alkyl group having a carbon number of 1 to 10; at least some of the hydrogen atoms in the hydrocarbon group, the acyl group, and the alkoxy group are optionally substituted with halogen atoms, hydroxy groups, carboxy groups, nitro groups, cyano groups, or —NR¹³R¹⁴s; the hydrocarbon group and the hydrocarbon group in the alkoxy group are optionally divided by an ether bond, a thioether bond, an ester bond, a thioester bond, an amide bond, or a urethane bond; R¹⁵ represents an alkyl group having a carbon number of 1 to 5; a represents an integer of 0 to 5 and b represents an integer of 0 to 4.

3. The photosensitive resin composition according to claim 1, wherein the photopolymerization initiator (d) has a structure represented by the following general formula (1-2): 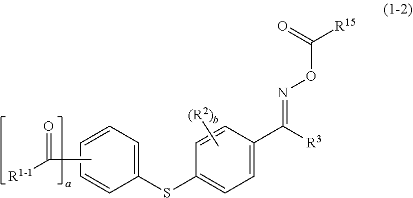
in the general formula (1-2), R¹⁻¹ represents a halogen atom, a hydroxy group, a carboxy group, a nitro group, a cyano group, —NR¹³R¹⁴, a monovalent hydrocarbon group having a carbon number of 1 to 20, or an alkoxy group having a carbon number of 1 to 20; R¹³ and R¹⁴ in R¹⁻¹ each independently represents a hydrogen atom or an alkyl group having a carbon number of 1 to 10; at least some of the hydrogen atoms in the hydrocarbon group and the alkoxy group in R¹¹ are optionally substituted with halogen atoms, hydroxy groups, carboxy groups, nitro groups, cyano groups, or —NR¹³R¹⁴s; the hydrocarbon group and the hydrocarbon group in the alkoxy group in R¹⁻¹ are optionally divided by an ether bond, a thioether bond, an ester bond, a thioester bond, an amide bond, or a urethane bond; R² and R³ each independently represents a halogen atom, a hydroxy group, a carboxy group, a nitro group, a cyano group, —NR¹³R¹⁴, a monovalent hydrocarbon group having a carbon number of 1 to 20, an acyl group having a carbon number of 1 to 20, or an alkoxy group having a carbon number of 1 to 20; R¹³ and R¹⁴ in R² and R³ each independently represents a hydrogen atom or an alkyl group having a carbon number of 1 to 10; at least some of the hydrogen atoms in the hydrocarbon group, the acyl group, and the alkoxy group in R² and R³ are optionally substituted with halogen atoms, hydroxy groups, carboxy groups, nitro groups, cyano groups, or —NR¹³R¹⁴s; the hydrocarbon group and the hydrocarbon group in the alkoxy group in R² and R³ are optionally divided by an ether bond, a thioether bond, an ester bond, a thioester bond, an amide bond, or a urethane bond; R¹⁵ represents an alkyl group having a carbon number of 1 to 5; a represents an integer of 0 to 5 and b represents an integer of 0 to 4.

4. The photosensitive resin composition according to claim 1, wherein when an absorbance before exposure at a wavelength of 405 nm is determined to be Abs(0) and an absorbance after exposure at a wavelength of 405 nm is determined to be Abs(1), the photosensitive resin composition satisfies Abs(1)/Abs(0)<1.25.

5. The photosensitive resin composition according to claim 1, wherein the alkali-soluble polyimide (a) has at least one of a carboxy group, a phenolic hydroxy group, a sulfonic acid group, and a thiol group at an end of a main chain.

6. The photosensitive resin composition according to claim 1, wherein the alkali-soluble polyimide (a) has at least one of a carboxy group, a phenolic hydroxy group, a sulfonic acid group, and a thiol group in a side chain.

7. The photosensitive resin composition according to claim 6, wherein the alkali-soluble polyimide (a) has the phenolic hydroxy group in the side chain.

8. The photosensitive resin composition according to claim 1, wherein the alkali-soluble polyimide (a) is a polyimide having a residue of a siloxanediamine.

9. The photosensitive resin composition according to claim 8, wherein the alkali-soluble polyimide (a) is a polyimide containing the residue of the siloxane diamine in an amount of 1% by mole or more and 10% by mole or less in total diamine residues.

10. The photosensitive resin composition according to claim 1, wherein an imidation ratio of the alkali-soluble polyimide (a) is 70% or more.

11. A photosensitive resin composition film comprising the photosensitive resin composition according to claim 1.

12. An insulating film comprising a cured product of the photosensitive resin composition according to claim 1.

13. An electronic component comprising the insulating film according to claim 12.

14. The electronic component according to claim 13, comprising a hollow structure body including a roof part made of the insulating film.
